(19) United States
(12) Patent Application Publication
(10) Pub. No.: US 2024/0339573 A1
(43) Pub. Date: Oct. 10, 2024

(54) LIGHT-EMITTING DEVICE

(71) Applicant: NICHIA CORPORATION, Anan-shi (JP)

(72) Inventor: Norimasa YOSHIDA, Komatsushima-shi (JP)

(73) Assignee: NICHIA CORPORATION, Anan-shi (JP)

(21) Appl. No.: 18/745,364

(22) Filed: Jun. 17, 2024

Related U.S. Application Data
(63) Continuation of application No. PCT/JP2022/044982, filed on Dec. 6, 2022.

(30) Foreign Application Priority Data
Dec. 22, 2021 (JP) 2021-207832

(51) Int. Cl. H01L 33/58; H01L 25/075; H01L 25/16; H01L 27/15

(52) U.S. Cl. CPC H01L 33/58; H01L 25/0753; H01L 25/167; H01L 27/156

(57) ABSTRACT

A light-emitting device includes: an array light source comprising a plurality of light-emitting units arranged in an array pattern, each light-emitting unit including a light-emitting surface, wherein the light-emitting surfaces of adjacent ones of the light-emitting units are located at a first light-emitting surface interval; a first lens configured to cause light emitted by the array light source to irradiate a region to be irradiated; a movement mechanism configured to cause the first lens and the array light source to move relative to each other along a direction intersecting an optical axis of the first lens; and a control unit comprising one or more electrical circuits or one or more central processing units, the control unit configured to: control light emission of each of the plurality of light-emitting units in a predetermined period, and control operation of the movement mechanism.

### CROSS-REFERENCE TO RELATED APPLICATION

This is a bypass continuation of PCT Application No. PCT/JP2022/044982, filed on Dec. 6, 2022, which claims priority to Japanese Patent Application No. 2021-207832, filed on Dec. 22, 2021. The disclosures of these applications are hereby incorporated by reference in their entireties.

### BACKGROUND

The present disclosure relates to a light-emitting device.

In the related art, light-emitting devices including a light-emitting diode or the like are widely used. For example, JP 2008-122463 A discloses a configuration including a first light-emitting means, a second light-emitting means, and a lens disposed between a subject and the first and second light-emitting means, in which the first light-emitting means and the second light-emitting means are configured to move on a plane perpendicular to an optical axis of the lens to allow adjustment in a light amount and an irradiation angle.

### SUMMARY OF INVENTION

A light-emitting device is required to control a region to be partially irradiated with light in a region to be irradiated.

An object of embodiments according to the present disclosure is to provide a light-emitting device that can control a region to be partially irradiated with light in a region to be irradiated.

A light-emitting device according to an embodiment of the present disclosure includes: an array light source including a plurality of light-emitting units arranged in an array pattern; a first lens configured cause light emitted by the array light source to irradiate a region to be irradiated; a movement mechanism configured to cause the first lens and the array light source to move relative to each other along a direction intersecting with an optical axis of the first lens; and a control unit including: a light emission control unit configured to control light emission of each of the plurality of light-emitting units, and a movement control unit configured to control an operation of the movement mechanism. The light emission control unit is configured to control light emission of each of the plurality of light-emitting units within a predetermined period. The movement control unit is configured to control the operation of the movement mechanism such that the first lens and the array light source perform a relative movement within the predetermined period. The relative movement includes a first relative movement in which the first lens and the array light source move relative to each other along a first direction. Each of the plurality of light-emitting units has a light-emitting surface. The light-emitting surfaces of adjacent ones of the light-emitting units are located at a first light-emitting surface interval therebetween. A distance of the first relative movement is equal to or greater than a length of a shorter one of either the first light-emitting surface interval or a width of the light-emitting surface along the first direction.

A light-emitting device according to an embodiment of the present disclosure includes: an array light source including: a plurality of light-emitting units arranged in an array pattern, and a light-emitting surface shared by two or more light-emitting units of the plurality of light-emitting units; a first lens configured to cause light emitted by the array light source to irradiate a region to be irradiated; a movement mechanism configured to cause the first lens and the array light source to move relative to each other along a direction intersecting with an optical axis of the first lens; and a control unit including: a light emission control unit configured to control light emission of each of the plurality of light-emitting units, and a movement control unit configured to control an operation of the movement mechanism. The light emission control unit is configured to control light emission of each of the plurality of light-emitting units within a predetermined period. The movement control unit is configured to control the operation of the movement mechanism such that the first lens and the array light source perform a relative movement within the predetermined period. The relative movement includes a first relative movement in which the first lens and the array light source move relative to each other along a first direction. Adjacent ones of the light-emitting units are disposed along the first direction at a first light-emitting unit interval. A distance of the first relative movement is equal to or greater than a length of a shorter one of either the first light-emitting unit interval or a width of the light-emitting unit along the first direction.

### Advantageous Effects of Invention

According to the embodiments of the present disclosure, it is possible to provide a light-emitting device that can control a region to be partially irradiated with light in a region to be irradiated.

### BRIEF DESCRIPTION OF THE DRAWINGS

FIG. 1 is a diagram for describing partial irradiation of light by a light-emitting device according to an embodiment.

FIG. 2 is a cross-sectional view illustrating an exemplary overall configuration of a light-emitting device according to a first embodiment.

FIG. 3 is a plan view of an array light source included in the light-emitting device of FIG. 2 as viewed from a first lens side.

FIG. 4 is a cross-sectional view taken along III-III in FIG. 3.

FIG. 5 is a plan view, in which a housing and a transparent member are not shown, of the light-emitting device in FIG. 2 as viewed from the first lens side.

FIG. 6 is a cross-sectional view taken along V-V in FIG. 5.

FIG. 7 is a plan view in which the first lens has moved to the +X direction side from the state of FIG. 5.

FIG. 8 is a cross-sectional view taken along VII-VII in FIG. 7.

FIG. 9 is a block diagram exemplifying a functional configuration of a control unit in the light-emitting device of FIG. 2.

FIG. 10 is a plan view illustrating a state in which the first lens has moved to the −X and −Y direction sides with respect to the center axis of the array light source in the light-emitting device of FIG. 2.

FIG. 11 is a cross-sectional view taken along XA-XA in FIG. 10.

FIG. 12 is a cross-sectional view taken along XB-XB in FIG. 10.

FIG. 13 is a diagram of exemplary irradiation light when the light-emitting device of FIG. 2 is in the state of FIG. 10.

FIG. 14 is a plan view illustrating a state in which the first lens has moved to the +X and −Y direction sides with respect to the center axis of the array light source in the light-emitting device of FIG. 2.

FIG. 15 is a cross-sectional view taken along XIVA-XIVA in FIG. 14.

FIG. 16 is a cross-sectional view taken along XIVB-XIVB in FIG. 14.

FIG. 17 is a diagram of exemplary irradiation light when the light-emitting device of FIG. 2 is in the state of FIG. 14.

FIG. 18 is a plan view illustrating a state in which the first lens has moved to the +X and +Y direction sides with respect to the center axis of the array light source in the light-emitting device of FIG. 2.

FIG. 19 is a cross-sectional view taken along XVIIIA-XVIIIA in FIG. 18.

FIG. 20 is a cross-sectional view taken along XVIIIB-XVIIIB in FIG. 18.

FIG. 21 is a diagram of exemplary irradiation light when the light-emitting device of FIG. 2 is in the state of FIG. 18.

FIG. 22 is a plan view illustrating a state in which the first lens has moved to the −X and +Y direction sides with respect to the center axis of the array light source in the light-emitting device of FIG. 2.

FIG. 23 is a cross-sectional view taken along XXIIA-XXIIA in FIG. 22.

FIG. 24 is a cross-sectional view taken along XXIIB-XXIIB in FIG. 22.

FIG. 25 is a diagram of an exemplary irradiation light when the light-emitting device of FIG. 2 is in the state of FIG. 22.

FIG. 26 is a diagram of an exemplary synthesis of the irradiation light in FIGS. 13, 17, 21, and 25.

FIG. 27 is a timing chart exemplifying an operation of the light-emitting device of FIG. 2.

FIG. 28A is a cross-sectional view illustrating an exemplary configuration of a light-emitting device according to a second embodiment.

FIG. 28B is a diagram for describing light rays when a second lens is a concave lens.

FIG. 29 is a diagram exemplifying light irradiated by the light-emitting device according to the second embodiment.

FIG. 30 is a cross-sectional view illustrating a modified example of the array light source of the light-emitting device according to the second embodiment.

FIG. 31A is a cross-sectional view illustrating a first modified example of the second lens.

FIG. 31B is a diagram for describing light rays when the second lens is a convex lens.

FIG. 32 is a diagram for exemplifying light irradiated by the light-emitting device according to the first modified example of the second embodiment.

FIG. 33 is a cross-sectional view illustrating a second modified example of the second lens.

FIG. 34 is a cross-sectional view illustrating a third modified example of the second lens.

FIG. 35 is a cross-sectional view illustrating a fourth modified example of the second lens.

FIG. 36 is a cross-sectional view illustrating a fifth modified example of the second lens.

FIG. 37 is a cross-sectional view illustrating a modified example of a movement mechanism of a light-emitting device according to an embodiment.

FIG. 38 is a plan view in which the array light source has moved to the +X direction side from the state of FIG. 37.

FIG. 39 is a cross-sectional view illustrating a first modified example of an array light source of a light-emitting device according to an embodiment.

FIG. 40 is a cross-sectional view illustrating a second modified example of the array light source of a light-emitting device according to an embodiment.

FIG. 41 is a cross-sectional view illustrating a third modified example of the array light source of a light-emitting device according to an embodiment.

FIG. 42 is a cross-sectional view illustrating a fourth modified example of the array light source of a light-emitting device according to an embodiment.

FIG. 43 is a cross-sectional view illustrating a fifth modified example of the array light source of a light-emitting device according to an embodiment.

FIG. 44 is a cross-sectional view illustrating a sixth modified example of the array light source of a light-emitting device according to an embodiment.

FIG. 45 is a diagram illustrating a first modified example of a relative movement path of a light-emitting device according to an embodiment.

FIG. 46 is a diagram illustrating a second modified example of the relative movement path of a light-emitting device according to an embodiment.

FIG. 47 is a diagram illustrating a third modified example of the relative movement path of a light-emitting device according to an embodiment.

FIG. 48 is a diagram illustrating a fourth modified example of the relative movement path of a light-emitting device according to an embodiment.

### DETAILED DESCRIPTION

A light-emitting device according to embodiments of the present disclosure will be described in detail with reference to the drawings. The following embodiments exemplify a light-emitting device for embodying the technical concept of the present embodiment, but the present embodiment is not limited to the following embodiments. Further, dimensions, materials, shapes, relative arrangements, or the like of constituent members described in the embodiments are not intended to limit the scope of the present disclosure thereto, unless otherwise specified, and are merely exemplary. The size, positional relationship, or the like of members illustrated in each of the drawings may be exaggerated for clarity of description. Further, in the following description, members having the same terms and reference signs represent the same members or members made of the same material, and a detailed description of these members will be omitted as appropriate. As a cross-sectional view, an end view illustrating only a cut surface may be used.

In the drawings described below, directions are sometimes indicated by an X-axis, a Y-axis, and a Z-axis. An X direction along the X-axis indicates a predetermined direction in a light-emitting surface of a light-emitting unit of a light-emitting device according to an embodiment, a Y direction along the Y-axis indicates a direction orthogonal to the X direction in the light-emitting surface, and a Z-direction along the Z-axis indicates a direction orthogonal to the light-emitting surface. In other words, the light-emitting surface of the light-emitting unit is parallel to an XY plane, and the Z-axis is orthogonal to the XY plane. The X direction is an example of a first direction, and the Y direction is an example of a second direction.

Further, the direction in the X direction indicated by the arrow is the +X direction or the +X side, the direction opposite to the +X direction is the −X direction or the −X side, the direction in the Y direction indicated by the arrow is the +Y direction or the +Y side, and the direction opposite to the +Y direction is the −Y direction or the −Y side. The direction in the Z direction indicated by the arrow is the +Z direction or the +Z side, and the direction opposite to the +Z direction is the −Z direction or the −Z side. In the embodiment, the light-emitting unit of the light-emitting device emits light toward the +Z side as an example. Also, the expression in “a plan view” used in the embodiment refers to viewing the object in the Z direction. However, this does not limit the orientation of the light-emitting device during use, and the light-emitting device may be in any appropriate orientation. Further, in the present embodiment, a surface of the object when viewed from a position located further in the +Z direction or from the +Z side is an “upper surface”, and a surface of the object when viewed from a position located further in the −Z direction or the −Z side is a “lower surface”.

Also, an optical axis of a first lens is along the Z-axis. The phrases “along the X-axis”, “along the Y-axis”, or “along the Z-axis” in the embodiment described below includes a case in which an object is sloped within a range of +10° with respect to these axes.

A light-emitting device according to an embodiment includes an array light source including a plurality of light-emitting units arranged in an array, and the first lens that allows light emitted by the array light source to be irradiated to a region to be irradiated. The light-emitting device can irradiate a portion of a desired region, which is part of a region to be irradiated that can be irradiated with light by the light-emitting device itself, with light and change the partial irradiation region by switching a light-emitting unit that emits light among a plurality of light-emitting units.

As used herein, the “region to be irradiated” refers to a region that can be irradiated with light by the light-emitting device, that is, a region in which various partial irradiation regions can be obtained by switching a light-emitting unit that emits light among a plurality of light-emitting units. Also, “partial irradiation” refers to irradiating light to a part of the region to be irradiated with light.

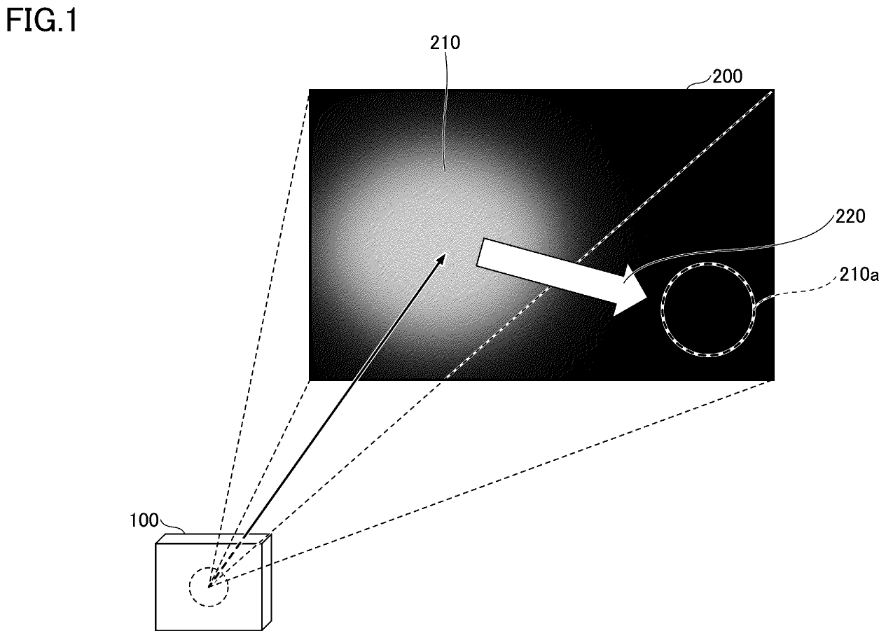

FIG. 1 is a diagram for describing partial irradiation of light by a light-emitting device 100 according to an embodiment. In FIG. 1, the light-emitting device 100 irradiates a partial irradiation region 210, which is a part of a region to be irradiated 200, with light and does not irradiate regions other than the partial irradiation region 210 with light. The partial irradiation region 210 is a region irradiated with light that is selectively caused to be emitted from some of light-emitting units among a plurality of light-emitting units.

The light-emitting device 100 is configured such that, in a stationary state in which the light-emitting device 100 is not moved, the size of the partial irradiation region 210 and the position of the partial irradiation region 210 in the direction of an arrow 220 can be changed by switching the light-emitting unit that emits light among the plurality of light-emitting units. In FIG. 1, the size of a partial irradiation region 210a is smaller than the size of the partial irradiation region 210. The partial irradiation region 210a whose position and size have been changed from the partial irradiation region 210 is formed by irradiation light from, among the plurality of light-emitting units, a reduced number of light-emitting units at the position switched corresponding to the direction of the arrow 220.

Such partial irradiation allows for, for example, when the light-emitting device 100 is used as a flash light source of an imaging device such as a camera, capturing a desired region such as the face of a person under a bright image capture condition while allowing its background to be clearly captured without irradiating the background with light.

In the partial irradiation, the larger the number of divisions of the region to be irradiated 200 is, the more natural partial irradiation light adjusted to the distance between the imaging device and the subject or the like can be obtained, and natural imaging of the subject by the imaging device or the like can be expected. The number of divisions of the region to be irradiated 200 refers to the number of regions that can be switched between irradiation and non-irradiation in the region to be irradiated 200. However, because the space of the light-emitting device itself in the imaging device is limited and the interval between the plurality of light-emitting units that are mountable is limited, the number of light-emitting units that are mountable on the light-emitting device and the number of divisions of the region to be irradiated 200 are limited in some cases.

In the present embodiment, the light-emitting device 100 includes a movement mechanism configured to cause the first lens and the array light source to move relative to each other along a direction intersecting with the optical axis of the first lens, and includes a control unit that includes a light emission control unit configured to control light emission of each of the plurality of light-emitting units and a movement control unit configured to control an operation of the movement mechanism. The light emission control unit is configured to control the light emission of each of the plurality of light-emitting units within a predetermined period, and the movement control unit is configured to perform control such that the first lens and the array light source are moved relative to each other within a predetermined period.

The predetermined period is, for example, an exposure period (shutter open period) of the imaging device in which the light-emitting device 100 is mounted. The light-emitting device 100 emits light from the plurality of light-emitting units while causing the first lens and the array light source to move relative to each other within the predetermined period, and combines the light emitted within the predetermined period, resulting in pseudo increase in the number of light-emitting units. Accordingly, a region to be partially irradiated with light in the region to be irradiated 200 can be more precisely controlled, so that the light-emitting device 100 that can emit natural irradiation light is provided.

Hereinafter, configurations and functions of the light-emitting device 100 will be described in detail using the light-emitting device 100 mounted on a smartphone and used as a flash light source for an imaging device provided in the smartphone as an example.

Examples of the imaging device include a camera for capturing a still image and a video camera for capturing a moving image. In the embodiments described below, the exposure period of the imaging device is an example of the predetermined period, but an imaging cycle of the imaging device may be set as the predetermined period.

### First Embodiment

### Exemplary Configuration of Light-Emitting Device 100

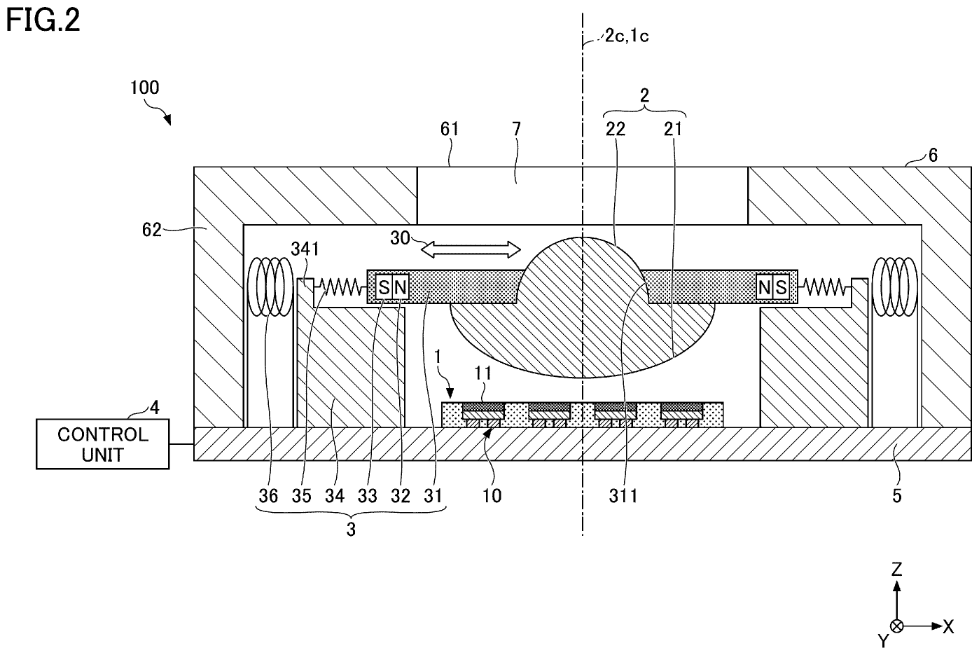

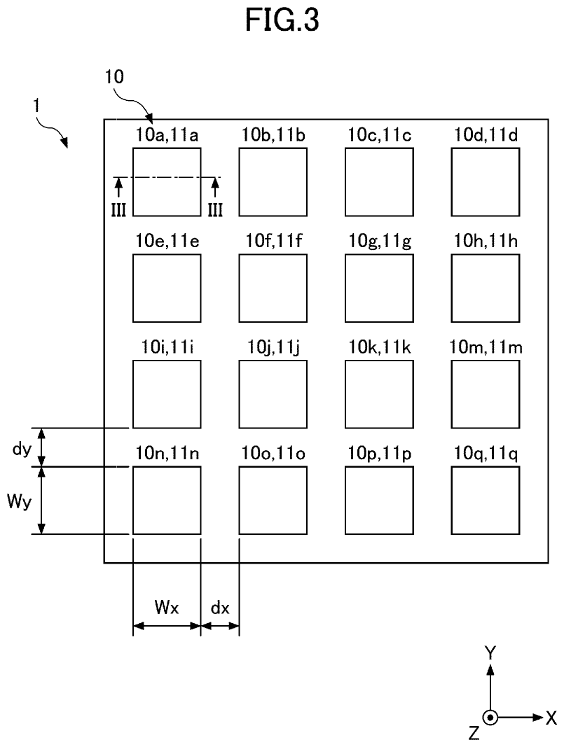

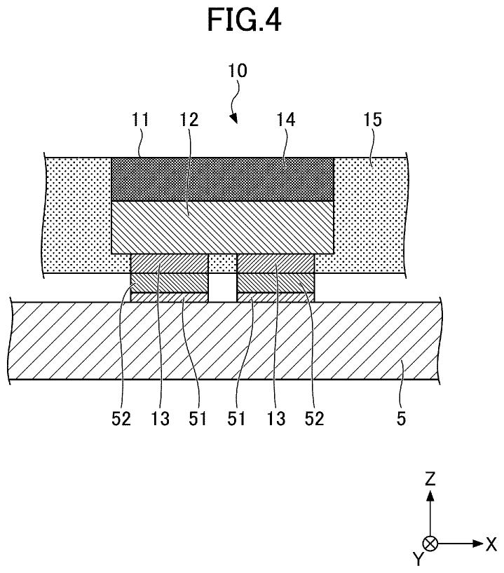

The configurations of the light-emitting device 100 according to a first embodiment will be described with reference to FIGS. 2 to 9. FIG. 2 is a cross-sectional view illustrating an example of an overall configuration of the light-emitting device 100. FIG. 3 is a plan view of an array light source 1 as viewed from a first lens 2 side. FIG. 4 is a cross-sectional view taken along line III-III in FIG. 3.

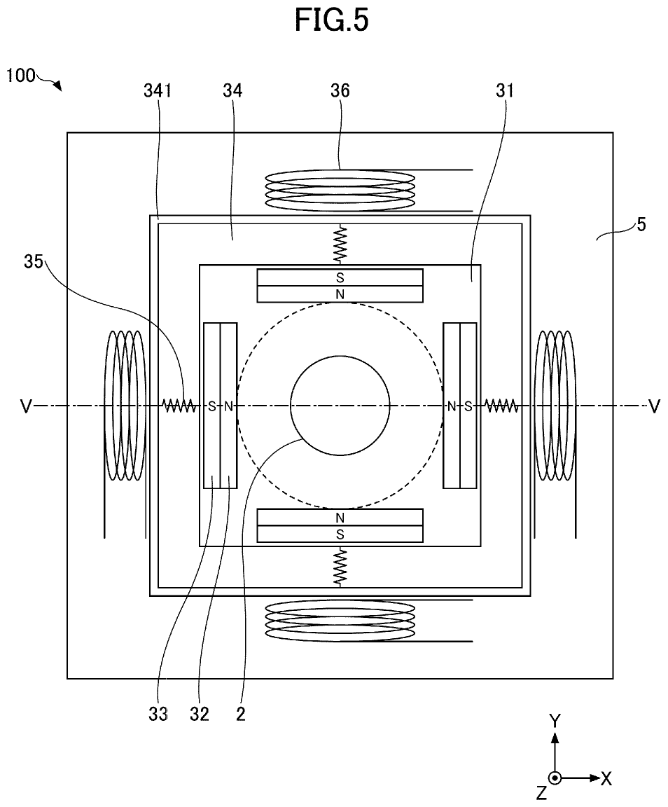

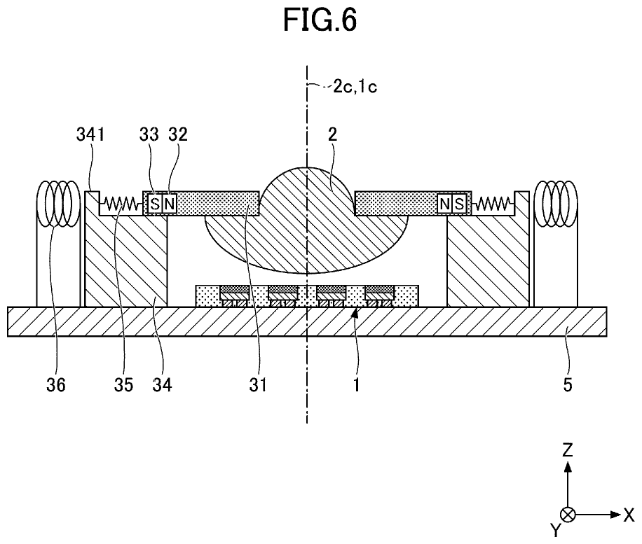

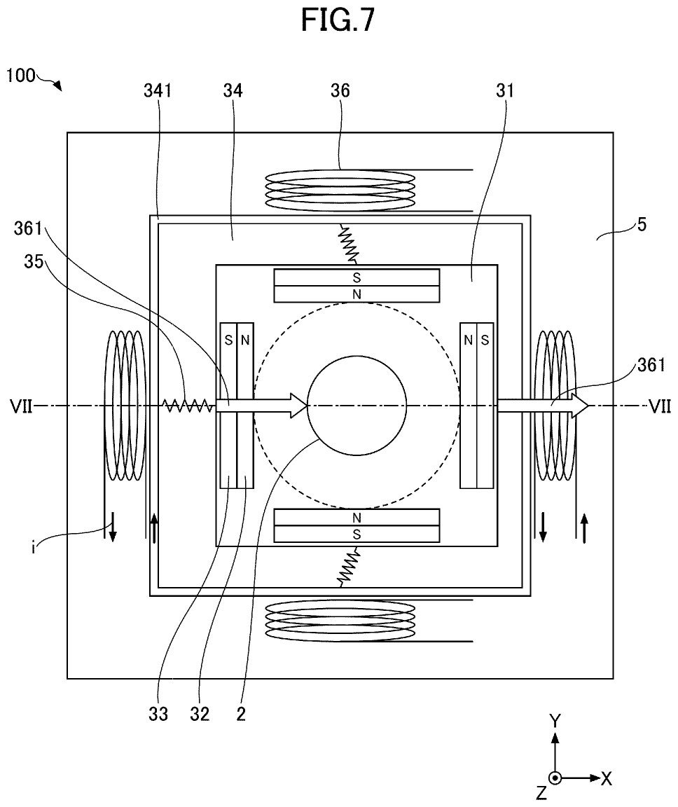

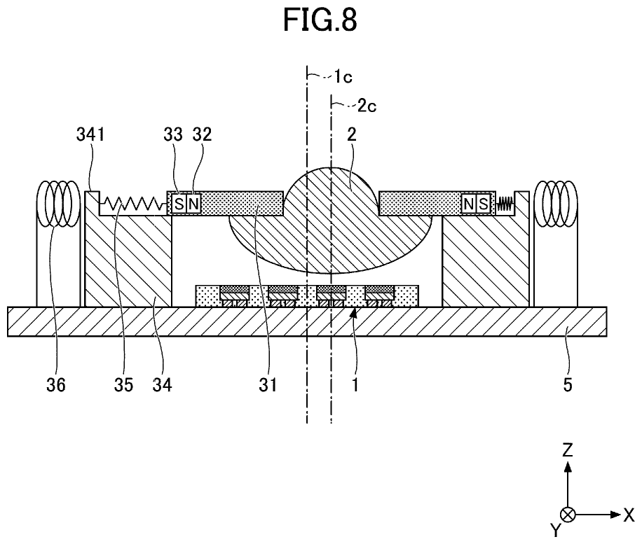

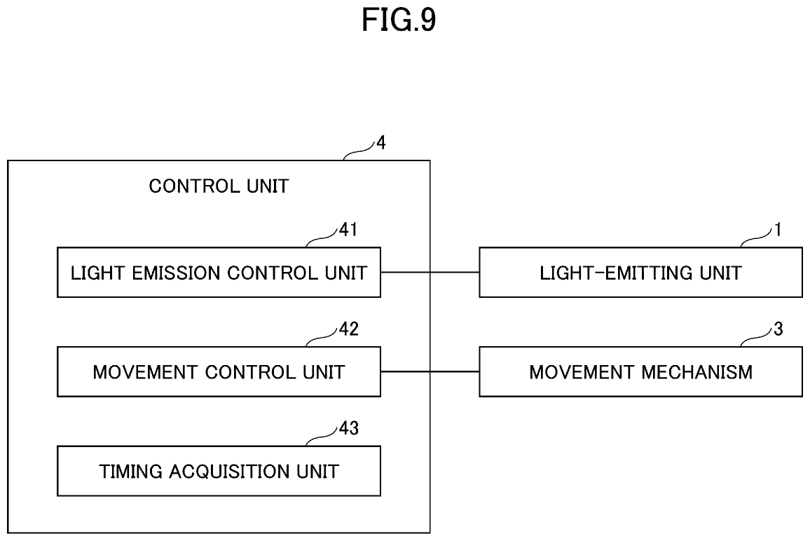

FIG. 5 is a plan view, in which a housing 6 and a transparent member 7 are not shown, of the light-emitting device 100 as viewed from the first lens 2 side. FIG. 6 is a cross-sectional view taken along V-V in FIG. 5. FIG. 7 is a plan view illustrating a state in which the first lens 2 has moved to the +X direction side from the state of FIG. 5. FIG. 8 is a cross-sectional view taken along VII-VII in FIG. 7. FIG. 9 is a block diagram exemplifying a functional configuration of a control unit 4 in the light-emitting device 100.

### Overall Configuration

As illustrated in FIG. 2, the light-emitting device 100 includes an array light source 1, the first lens 2, a movement mechanism 3, and the control unit 4.

The array light source 1 includes a plurality of light-emitting units 10 arranged in an array pattern. Each of the plurality of light-emitting units 10 is formed into a substantially rectangular shape in a plan view and is mounted on a +Z-side surface (in other words, an upper surface) of a light-emitting unit mounting substrate 5.

The light-emitting unit mounting substrate 5 is a plate-like member having a substantially rectangular shape in a plan view and is a substrate provided with wiring on which a light-emitting element or various electrical elements are mountable. The housing 6 is provided on the light-emitting unit mounting substrate 5, and the transparent member 7 is disposed inside an opening 61 of the housing 6. The transparent member 7 overlaps with the array light source 1 and the first lens 2 in a plan view.

Each of the plurality of light-emitting units 10 includes a light-emitting surface 11, and emits light toward the first lens 2 provided on the +Z side of the array light source 1.

The “light-emitting surface 11” refers to a main light extraction surface of the light-emitting unit 10. A Light Emitting Diode (LED) or the like can be used for the light-emitting unit 10. The light emitted by the light-emitting unit 10 is preferably white light, but may be monochromatic light. By selecting the light-emitting unit 10 in accordance with the use of the light-emitting device 100, the light emitted by the light-emitting unit 10 can be selected as appropriate.

The first lens 2 is configured to allow the light emitted by the array light source 1 to irradiate the region to be irradiated 200. The region to be irradiated 200 is a region on the +Z side of the light-emitting device 100.

In the present embodiment, the first lens 2 is a biconvex single lens including a first convex surface 21 protruding to the array light source 1 side and a second convex surface 22 protruding to the side opposite to the array light source 1 side. The curvature radius of the first convex surface 21 is larger than the curvature radius of the second convex surface 22. The first lens 2 is formed into a substantially circular outer shape in a plan view.

However, the first lens 2 is not limited to this configuration, and may be a concave lens or a meniscus lens, or may be a combined lens formed of a plurality of lenses or the like. The size of the curvature radius, the thickness of the lens, and the like can also be changed as appropriate. The plan view shape of the outer shape of the first lens 2 is not limited to a substantially circular shape, but may be a substantially rectangular shape, a substantially triangular shape, a substantially elliptical shape, a substantially polygonal shape, or the like. Considering that the image capture area of a typical imaging device has a substantially rectangular shape, the plan view shape of the first lens 2 is preferably a shape having four-fold rotational symmetry or a shape having two-fold rotational symmetry shape.

The first lens 2 is optically transmissive to light emitted by the light-emitting unit 10 and includes at least one of a resin material, such as polycarbonate resin, acrylic resin, silicone resin, epoxy resin, or the like, or a glass material. “Optically transmissive” here refers to a property that allows 60% or more of the light from the light-emitting unit 10 to be transmitted.

The movement mechanism 3 is provided on the +Z side of the light-emitting unit mounting substrate 5, and is an electromagnetic actuator configured to cause the first lens 2 and the array light source 1 to move relative to each other along a movement direction 30. The movement direction 30 is a direction substantially orthogonal to an optical axis 2c of the first lens 2 and is an example of a direction intersecting with the optical axis 2c of the first lens 2. In the present embodiment, the term “intersect” includes a range within +10° from being orthogonal.

The movement mechanism 3 moves the first lens 2 and thereby causes the first lens 2 and the array light source 1 to move relative to each other. The optical axis 2c of the first lens 2 can also be referred to as a center axis of the first lens 2.

The movement direction 30 is a direction substantially parallel to the light-emitting surface 11 and substantially parallel to the +Z-side surface of the light-emitting unit mounting substrate 5.

In FIG. 2, the optical axis 2c of the first lens 2 and a center axis 1c of the array light source 1 substantially coincide with each other, and accordingly the reference numeral of the center axis 1c of the array light source 1 is written together with the reference sign of the optical axis 2c of the first lens 2. Also in the following description, when two or more components substantially coincide or overlap with each other, reference signs are written together in some cases.

The control unit 4 is an electrical circuit that is electrically connected to the array light source 1 and the movement mechanism 3 in a wired or wireless manner and is configured to control operations of the array light source 1 and the movement mechanism 3.

The control unit 4 supplies a drive signal to each of the array light source 1 and the movement mechanism 3 via the light-emitting unit mounting substrate 5. The control unit 4 may be mounted at any appropriate position, and may be installed either inside or outside the housing 6.

In the case of wireless connection, the control unit 4 may be disposed remotely from the housing 6.

The housing 6 is a box-like member having a substantially rectangular shape in a plan view that can internally house the array light source 1, the first lens 2, and the movement mechanism 3. A part of a housing of a smartphone on which the light-emitting device 100 is mounted may serve as the housing 6. The housing 6 includes the opening 61 and a transparent member holding portion 62.

The opening 61 has a substantially circular shape in a plan view. The opening 61 is preferably larger than the first lens 2 in a plan view such that the first lens 2 is located inside the opening 61 in a plan view. The −Z-side surface of the transparent member holding portion 62 is fixed to the +Z-side surface of the light-emitting unit mounting substrate 5 by an adhesive member or the like.

The housing 6 is preferably formed of a member having a light-shielding property and preferably contains a resin material or the like containing a filler, such as a light reflecting member or a light absorbing member, such that the distribution direction of the light emitted from the light-emitting device 100 can be restricted.

The transparent member 7 is a plate-like member having a substantially circular shape in a plan view and includes a resin material or a glass material that is optically transmissive to at least the light emitted by the light-emitting unit 10. The transparent member 7 is disposed on the +Z side of the first lens 2, and is supported in a state of being inserted into the opening 61 of the housing 6. The transparent member 7 may be adhered to the housing 6 by an adhesive member or the like.

The transparent member 7 is configured to transmit light that has been emitted from the first lens 2. After being emitted from the first lens 2, the light transmitted through the transparent member 7 serves as irradiation light emitted by the light-emitting device 100.

By housing the array light source 1, the first lens 2, the movement mechanism 3, and the like inside the space enclosed by the light-emitting unit mounting substrate 5, the housing 6, and the transparent member 7, it is possible to prevent foreign matter, such as dust or dirt, from adhering to the array light source 1, the first lens 2, the movement mechanism 3, and the like and from striking the first lens 2, the movement mechanism 3, and the like.

The shape of each of the housing 6 and the transparent member 7 is not limited to the shapes described above, and a housing 6 with a substantially circular shape, a substantially elliptical shape, or a substantially polygonal shape in a plan view may be used, and a transparent member 7 with a substantially rectangular shape, a substantially elliptical shape, or a substantially polygonal shape in a plan view may be used.

### Array Light Source 1

As illustrated in FIGS. 3 and 4, the array light source 1 includes 16 light-emitting units 10 constituted of light-emitting units 10a, 10b, 10c, 10d, 10e, 10f, 10g, 10h, 10i, 10j, 10k, 10m, 10n, 100, 10p, and 10q that are arranged vertically, horizontally, or in a lattice pattern in a plan view. The plurality of light-emitting units 10 are arranged along the X direction, or arranged along the X direction and the Y direction orthogonal to the X direction. In FIG. 3, the plurality of light-emitting units 10 are arranged along the X direction and the Y direction.

The light-emitting unit 10a includes a light-emitting surface 11a, the light-emitting unit 10b includes a light-emitting surface 11b, the light-emitting unit 10c includes a light-emitting surface 11c, the light-emitting unit 10d includes a light-emitting surface 11d, the light-emitting unit 10e includes a light-emitting surface 11e, the light-emitting unit 10f includes a light-emitting surface 11f, and the light-emitting unit 10g includes a light-emitting surface 11g. The light-emitting unit 10h includes a light-emitting surface 11h, the light-emitting unit 10i includes a light-emitting surface 11i, the light-emitting unit 10j includes a light-emitting surface 11j, the light-emitting unit 10k includes a light-emitting surface 11k, the light-emitting unit 10m includes a light-emitting surface 11m, the light-emitting unit 10n includes a light-emitting surface 11n, the light-emitting unit 10p includes a light-emitting surface 11p, and the light-emitting unit 10q includes a light-emitting surface 11q. The light-emitting unit 10 and the light-emitting surface 11 overlap with each other in a plan view, and accordingly the reference sign of the light-emitting unit 10 and the reference sign of the light-emitting surface 11 are written together in FIG. 3.

It is preferable that the light-emitting surface 11a to the light-emitting surface 11q are disposed on an inner side of the first lens 2 (on an inner side with respect to the outer shape of the first lens 2) in a plan view.

A width Wx represents the width of each of the light-emitting surface 11a to the light-emitting surface 11q along the X direction. A width Wy represents the width of each of the light-emitting surface 11a to the light-emitting surface 11q along the Y direction. A first light-emitting surface interval dx represents the interval along the X direction between adjacent light-emitting surfaces 11 of the light-emitting surface 11a to the light-emitting surface 11q. A second light-emitting surface interval dy represents the interval along the Y direction between adjacent light-emitting surfaces 11 of the light-emitting surface 11a to the light-emitting surface 11q.

In the present embodiment, the width Wx is longer than the first light-emitting surface interval dx, and the width Wy is longer than the second light-emitting surface interval dy.

In terms of light emission characteristics of the light-emitting device 100, it is preferable that the first light-emitting surface interval dx and the second light-emitting surface interval dy are as narrow as possible. However, the interval at which the plurality of light-emitting units 10 are mountable is limited. In order to achieve both obtaining good light emission characteristics and an interval at which the plurality of light-emitting units 10 are mountable, the first light-emitting surface interval dx is preferably in a range from 0.05 [mm] to 2.00 [mm]. Similarly, the second light-emitting surface interval dy is also preferably in a range from 0.05 [mm] to 2.00 [mm].

In FIG. 3, 16 light-emitting units 10 that are arranged vertically, horizontally, or in a lattice pattern have been exemplified.

However, the arrangement and number of the light-emitting units 10 are not limited thereto. It is sufficient to include at least two light-emitting units 10, and the arrangement and number of the light-emitting units 10 can be adjusted as appropriate in accordance with the use of the light-emitting device 100 or the like.

### Light-Emitting Unit 10

As illustrated in FIG. 4, the light-emitting unit 10 is mounted on the +Z-side surface of the light-emitting unit mounting substrate 5 with the +Z-side surface of the light-emitting unit 10 serving as the light-emitting surface 11 and the surface of the light-emitting unit 10 on the side opposite to the light-emitting surface 11 serving as a mounting surface.

The light-emitting unit 10 includes a light-emitting element 12, a light-transmitting member 14 located on the +Z side of the light-emitting element 12, and a covering member 15 that covers a lateral surface of the light-emitting element 12 and a lateral surfaces of the light-transmitting member 14 without covering the +Z-side surface of the light-transmitting member 14.

At least a pair of positive and negative electrodes 13 are preferably provided at a surface of the light-emitting element 12 on the side opposite to the light-emitting surface 11. In the present embodiment, the shape of the light-emitting surface 11 in a plan view is a substantially rectangular shape, but may be a substantially circular shape, a substantially elliptical shape, or a polygonal shape, such as a substantially triangular shape or a substantially hexagonal shape.

The light-emitting element 12 is preferably formed of various semiconductors, such as a III-V compound semiconductor or a II-VI compound semiconductor. As the semiconductor, preferably, a nitride-based semiconductor such as In_{X}Al_{Y}Ga_{1-X-Y}N (0≤X, 0≤Y, X+Y≤1) or the like is used, and InN, AlN, GaN, InGaN, AlGaN, InGaAlN, and the like can also be used.

The light-transmitting member 14 is a plate-shaped member having a substantially rectangular shape in a plan view and covers an upper surface of the light-emitting element 12. The light-transmitting member 14 can be formed using a light-transmissive resin material or an inorganic material, such as ceramic or glass. As the resin material, a thermosetting resin, such as a silicone resin, a silicone modified resin, an epoxy resin, an epoxy modified resin, or a phenol resin, can be used. Particularly, a silicone resin or a modified resin thereof with good light resistance and heat resistance is preferably used. The term “light-transmitting” as used herein preferably indicates transmitting 60% or more of the light from the light-emitting element 12 being transmitted.

Further, as the light-transmitting member 14, a thermoplastic resin, such as a polycarbonate resin, an acrylic resin, a methyl pentene resin, or a polynorbornene resin, can be used.

Further, the light-transmitting member 14 may be formed of the resin described above and a wavelength conversion member that converts the wavelength of at least a part of light from a light diffusion member or the light-emitting element 12. Examples of the light-transmitting member 14 formed of a resin and a wavelength conversion member include a member containing a wavelength conversion member in a resin material, ceramic, glass, or the like, a sintered body for a wavelength conversion member, and the like. The light-transmitting member 14 may be a multi-layered member formed by disposing a resin layer containing a wavelength conversion member or a light diffusion member on the ±Z-side surfaces of a molded body, such as a resin, ceramic, glass, or the like.

As the wavelength conversion member included in the light-transmitting member 14, an yttrium aluminum garnet based phosphor (for example, Y₃(Al, Ga)₅O₁₂:Ce), a lutetium aluminum garnet based phosphor (for example, Lu₃(Al, Ga)₅O₁₂:Ce), a terbium aluminum garnet based phosphor (for example, Tb₃(Al, Ga)₅O₁₂:Ce), a CCA based phosphor (for example, Ca₁₀(PO₄)₆Cl₂:Eu), an SAE based phosphor (for example, Sr₄Al₁₄O₂₅:Eu), a chlorosilicate based phosphor (for example, Ca₈MgSi₄O₁₆Cl₂:Eu), a nitride based phosphor, a fluoride based phosphor, a phosphor having a perovskite structure (for example, CsPb (F, Cl, Br, I)₃), and a quantum dot phosphor (for example, CdSe, InP, AgInS₂, AgInSe₂, AgInGaS₂, CuAgInS₂), or the like can be used. Examples of a nitride phosphor include a β-sialon based phosphor (for example, (Si, Al)₃(O, N)₄:Eu), an α-sialon based phosphor (for example, Ca (Si, Al)₁₂(O, N)₁₆:Eu), an SLA based phosphor (for example, SrLiAl₃N₄:Eu), a CASN based phosphor (for example, CaAlSiN₃:Eu), a SCASN based phosphor (for example, (Sr, Ca)AlSiN₃:Eu), and the like; and examples of a fluoride based phosphor include a KSF based phosphor (for example, K₂SiF₆:Mn), a KSAF based phosphor (for example, K₂(Si, Al)F₆:Mn), and an MGF based phosphor (for example, 3.5 MgO 0.5 MgF₂·GeO₂:Mn). The phosphors described above are particles. Further, one type of these wavelength conversion members can be used alone, or two or more types of these wavelength conversion members can be used in combination.

The KSAF based phosphor may have a composition represented by Formula (I).

M₂[SiₚAl_{q}MnᵣFₛ] (I)

In Formula (I), M represents an alkali metal and may include at least K. Mn may be a tetravalent Mn ion. p, q, r, and s may satisfy 0.9≤p+q+r≤1.1, 0<q≤0.1, 0<r≤0.2, 5.9≤s≤6.1. Preferably 0.95≤p+q+r≤1.05 or 0.97≤p+q+r≤1.03, 0<q≤0.03, 0.002≤q≤0.02 or 0.003≤q≤0.015, 0.005≤r≤0.15, 0.01≤r≤0.12 or 0.015≤r≤0.1, 5.92≤s≤6.05 or 5.95≤s≤6.025 may be satisfied. Examples of the composition represented by Formula (I) include compositions represented by K₂ [Si_{0.946}Al_{0.005}Mn_{0.049}F_{5.995}], K₂ [Si_{0.942}Al_{0.008}Mn_{0.050}F_{5.992}], K₂ [Si_{0.939}Al_{0.014}Mn_{0.047}F_{5.986}]. Such a KSAF based phosphor enables red light emission having a high luminance and a narrow half-value width of the light emission peak wavelength.

According to the embodiment, in the light-emitting device 100, a blue light-emitting element is used as the light-emitting element 12, the light-transmitting member 14 contains a wavelength conversion member for wavelength-converting the light emitted from the light-emitting element 12 into yellow light, and thus white light is emitted.

As the light diffusion member included in the light-transmitting member 14, for example, titanium oxide, barium titanate, aluminum oxide, silicon oxide, and the like can be used.

The covering member 15 is a member that covers the lateral surfaces of the light-emitting element 12 and the lateral surfaces of the light-transmitting member 14 and covers the lateral surfaces of the light-emitting element 12 and the light-transmitting member 14 directly or indirectly. An upper surface of the light-transmitting member 14 is exposed from the covering member 15, and is the light-emitting surface 11 of the light-emitting unit 10.

The covering member 15 may provide separation between adjacent ones of light-emitting units 10.

The covering member 15 is preferably formed by a member having a high light reflectivity in order to improve light extraction efficiency. For the covering member 15, a resin material containing a light-reflective material, such as white pigment, for example, can be used.

Examples of the light reflective material include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide.

It is preferable to use one type of these alone, or to use two or more types of these in combination.

As a base material of the resin material, a resin material containing a thermosetting resin such as an epoxy resin, an epoxy modified resin, a silicone resin, a silicone modified resin, or a phenol resin as a main component is preferably used. The covering member 15 may be formed by a member having light transmissivity with respect to visible light as necessary.

The light-emitting unit mounting substrate 5 is preferably provided with wirings 51 disposed on a surface and/or inside of the light-emitting unit mounting substrate 5. In the light-emitting unit mounting substrate 5, the light-emitting unit mounting substrate 5 and the light-emitting unit 10 are electrically connected by connecting each of the wirings 51 and a corresponding one of at least the positive and negative pair of electrodes 13 of the light-emitting unit 10 via a corresponding one of conductive adhesive members 52. The configuration, size, and the like of the wirings 51 of the light-emitting unit mounting substrate 5 are set according to the configuration and size of the electrodes 13 of the light-emitting unit 10.

As a base material of the light-emitting unit mounting substrate 5, an insulating material is preferably used, a material that does not easily transmit the light emitted from the light-emitting unit 10, outside light, or the like is preferably used, and a material with a certain amount of strength is preferably used. Specifically, the light-emitting unit mounting substrate 5 can be formed of a ceramic, such as alumina, aluminum nitride, mullite, or silicon nitride, or a resin, such as phenol resin, epoxy resin, polyimide resin, BT resin (bismaleimide triazine resin), polyphthalamide, or the like, as a base material thereof.

The wiring 51 can be formed of at least one type of copper, iron, nickel, tungsten, chromium, aluminum, silver, gold, titanium, palladium, rhodium, alloys thereof, or the like. Further, considering wettability and/or light reflectivity or the like of the conductive adhesive member 52, a surface layer of the wiring 51 may be provided with a layer of silver, platinum, aluminum, rhodium, gold, alloys thereof, or the like.

### Movement Mechanism 3

As illustrated in FIG. 2 and FIGS. 5 to 8, the movement mechanism 3 includes a frame portion 31, an N-pole magnet 32, an S-pole magnet 33, a platform portion 34, a spring 35, and a coil 36.

The frame portion 31 is a member having a substantially rectangular frame-like shape in a plan view. The frame portion 31 has an opening on an inner side thereof, the first lens 2 is disposed in the opening, and the second convex surface 22 of the first lens 2 and an inner lateral surface 311 of the opening of the frame portion 31 are bonded to each other by an adhesive member or the like, thereby supporting the first lens 2.

The frame portion 31 includes a resin material, a metal material, or the like. The frame portion 31 preferably includes, on surfaces or inside thereof, a color material, such as a black material, that can absorb light emitted by the light-emitting unit 10. With this configuration, light that leaks toward the frame portion 31 side through the first lens 2 can be absorbed by the frame portion 31, and therefore light reflected by the frame portion 31 can be inhibited from returning to the first lens 2 side. As a result, ghost light, flared light or the like associated with the return light can be reduced, and contrast of the irradiation light by the light-emitting device 100 can be increased.

The “contrast of the irradiation light” refers to the contrast between the partial irradiation region and the regions other than the partial irradiation region, among the region to be irradiated, which can be irradiated with light by the light-emitting device 100. When the contrast is high, the contrast between the partial irradiation region and the regions other than the partial irradiation region becomes larger, and thereby a more significant effect of the partial irradiation can be exhibited.

The N-pole magnets 32 and the S-pole magnets 33 are quadrangular columnar members that include a metal material or the like. Each N-pole magnet 32 is magnetized to be an N-pole magnet, and each S-pole magnet 33 is magnetized to be an S-pole magnet.

The N-pole magnet 32 and the S-pole magnet 33 form a pair, and four pairs of the N-pole magnets 32 and the S-pole magnets 33 are fixed inside respective sides of the frame portion 31. It is sufficient that the N-pole magnets 32 and the S-pole magnets 33 are fixed to the frame portion 31, and may be, for example, fixed to a surface, such as an outer lateral surface, of the frame portion 31 by an adhesive member or the like, or be accommodated in a recessed portion of the frame portion 31 and fixed by an adhesive member or the like.

The term “N-pole magnets 32” is a collective name for four N-pole magnets, and the term “S-pole magnets 33” is a collective name for four S-pole magnets. The numbers of the N-pole magnets 32 and the number of the S-pole magnets 33 are not limited to four, and any appropriate number of them may be employed.

The platform portion 34 is a member having a substantially rectangular frame-like shape in a plan view. The platform portion 34 is fixed on the +Z-side surface of the light-emitting unit mounting substrate 5 such that the first lens 2 is internally disposed. The frame portion 31 is movably mounted on the +Z-side surface of the platform portion 34. A wall portion 341 is provided on an outer portion of the platform portion 34, that is, on a portion on the side opposite to the side facing the first lens 2 of the platform portion 34.

The springs 35 are an elastic member that can expand and contract toward the optical axis 2c of the first lens 2. Any appropriate material may be used for the spring 35, and a metal material, a resin material, or the like can be used for the spring 35. The springs 35 include four springs arranged to surround the first lens 2, and respective springs of the springs 35 are located at positions that are point symmetrical with respect to the optical axis 2c of the first lens 2 when the optical axis 2c of the first lens 2 and the center axis 1c of the array light source 1 are substantially aligned. In other words, respective springs are arranged at positions that are point symmetrical with respect to the center of the transparent member 7 in a plan view to surround the first lens 2. The spring 35 is a collective name for four springs. The number of the springs 35 is not limited to four, and may be any appropriate number.

One end of the spring 35 is connected to the outer lateral surface of the frame portion 31, and the other end is connected to the wall portion 341 of the platform portion 34. The frame portion 31 is movable on the platform portion 34 together with the first lens 2. The spring 35 limits excessive movement of the frame portion 31, and imparts a restoring force to the frame portion 31 that causes the frame portion 31 to return to its initial position.

The coil 36 is a member that can conduct a current and is formed by winding a wire or the like into a spiral shape or a coil shape. The coil 36 includes four coils, and the coil 36 is a generic name for four coils. The four coils are paired with respective pairs of the four N-pole magnets 32 and the four S-pole magnets 33. Each of the four coils is disposed on a side opposite to a respective set of a respective one of the four N-pole magnets 32 and a respective one of the four S-pole magnets 33 across the wall portion 341 and the spring 35, and is fixed on the +Z-side surface of the light-emitting unit mounting substrate 5. The number of the coils 36 is not limited to four and may be any number in accordance with the number of the N-pole magnets 32 and the S-pole magnets 33.

As illustrated in FIG. 7, for example, when a drive current i is supplied from the control unit 4 to the coil 36, an electromagnetic force 361 is generated according to the right-hand rule by the action of the N-pole magnet 32, the S-pole magnet 33, and the coil 36. The white arrow representing the electromagnetic force 361 represents the direction of the electromagnetic force 361 received by the N-pole magnet 32 and the S-pole magnet 33. By the electromagnetic force 361 acting on the frame portion 31, the frame portion 31 moves along the direction in which the electromagnetic force 361 acts.

The magnitude of the electromagnetic force 361 changes in accordance with the amount of drive current i flowing through the coil 36, and thus the amount of movement of the frame portion 31 changes. Further, the direction of the electromagnetic force 361 changes in accordance with the direction of the drive current i flowing through the coil 36, and thus the movement direction of the frame portion 31 changes. For example, when the drive current i flows in a direction opposite to the direction in which the drive current i illustrated in FIG. 7 flows, an electromagnetic force is generated in a direction opposite to the direction indicated by the white arrow of the electromagnetic force 361. At this time, the frame portion 31 moves along the direction in which the generated electromagnetic force acts.

The movement mechanism 3 causes the first lens 2 and the array light source 1 to move relative to each other along the direction intersecting with the optical axis 2c of the first lens 2 by the electromagnetic force generated in each set of the coil 36 and the N-pole magnet 32 and the S-pole magnet 33 in accordance with the amount and direction of the drive current i flowing through each of the four coils 36. For example, the movement mechanism 3 can cause the first lens 2 to relatively move with respect to the array light source 1 in the XY plane intersecting with the +Z direction.

In the present embodiment, an electromagnetic actuator has been exemplified as the movement mechanism 3. The driving method of the movement mechanism 3 is not limited thereto, and other driving methods, such as a piezoelectric actuator or an ultrasonic actuator, can also be used.

### Control Unit 4

As illustrated in FIG. 9, the control unit 4 includes a light emission control unit 41, a movement control unit 42, and a timing acquisition unit 43. In addition to realizing the functions of the light emission control unit 41, the movement control unit 42, and the timing acquisition unit 43 by an electrical circuit, the control unit 4 can also realize some or all of these functions by a Central Processing Unit (CPU). The control unit 4 may realize these functions by a plurality of circuits or a plurality of processors.

The light emission control unit 41 controls light emission of each of the plurality of light-emitting units 10 in the array light source 1. For example, by controlling the drive current i applied to each of the plurality of light-emitting units 10, the light emission control unit 41 can control switching of the light-emitting unit 10 that emits light among the plurality of light-emitting units 10 and/or the intensity of light emitted by the light-emitting unit 10. Further, the light emission control unit 41 may control the light emission time of the light-emitting unit 10. In the embodiment, particularly, the light emission control unit 41 controls light emission of each of the plurality of light-emitting units 10 within the exposure period.

The movement control unit 42 controls the operation of the movement mechanism 3. For example, the movement control unit 42 can control the operation of the movement mechanism 3 by controlling the amount and direction of the drive current i applied to the coil 36. In the embodiment, particularly, the movement control unit 42 controls the operation of the movement mechanism 3 such that the first lens 2 and the array light source 1 perform the relative movement within the exposure period.

In the present embodiment, the movement of the first lens 2 and the array light source 1 relative to each other includes a first relative movement in which the first lens 2 and the array light source 1 move relative to each other along the X direction, and a second relative movement in which the first lens 2 and the array light source 1 move relative to each other along the Y direction.

The distance of the first relative movement performed by the movement control unit 42 is equal to or greater than the length of a shorter one of either the first light-emitting surface interval dx or the width Wx of the light-emitting surface 11 along the X direction. Also, the distance of the second relative movement performed by the movement control unit 42 is equal to or greater than the length of a shorter one of either the second light-emitting surface interval dy or the width Wy of the light-emitting surface 11 along the Y direction.

In the present embodiment, the length of the width Wx of the light-emitting surface 11 is longer than the length of the first light-emitting surface interval dx, so that the distance of the first relative movement is equal to or greater than the length of the first light-emitting surface interval dx. Also, the length of the width Wy of the light-emitting surface 11 is longer than the length of the second light-emitting surface interval dy, so that the distance of the second relative movement is equal to or greater than the second light-emitting surface interval dy.

The timing acquisition unit 43 acquires timing information, such as a signal indicating start or end of the exposure period in the imaging device, from the smartphone. The light emission control unit 41 and the movement control unit 42 can perform control according to the timing information acquired by the timing acquisition unit 43.

### Exemplary Operation of Light-Emitting Device 100

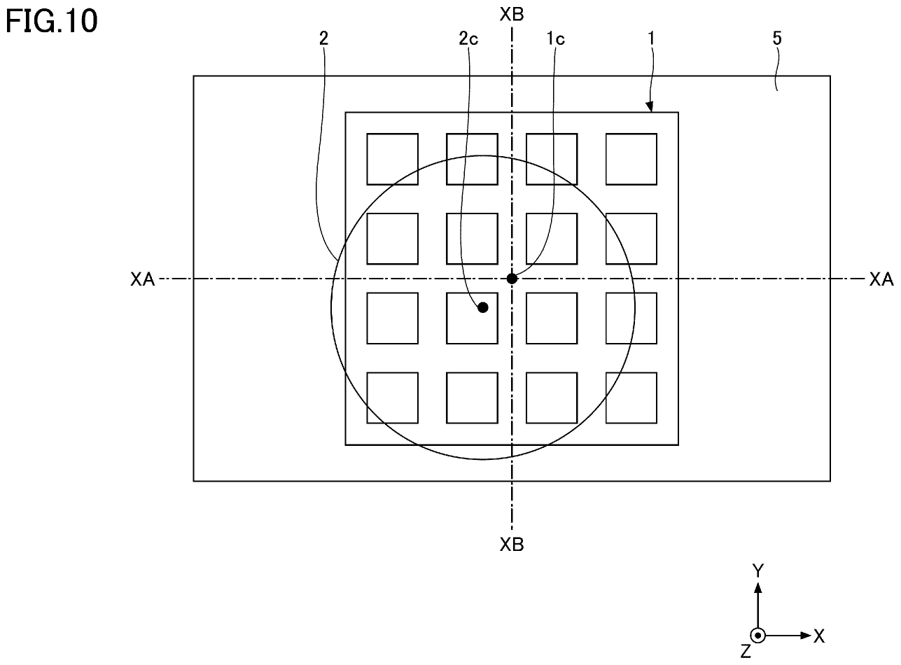

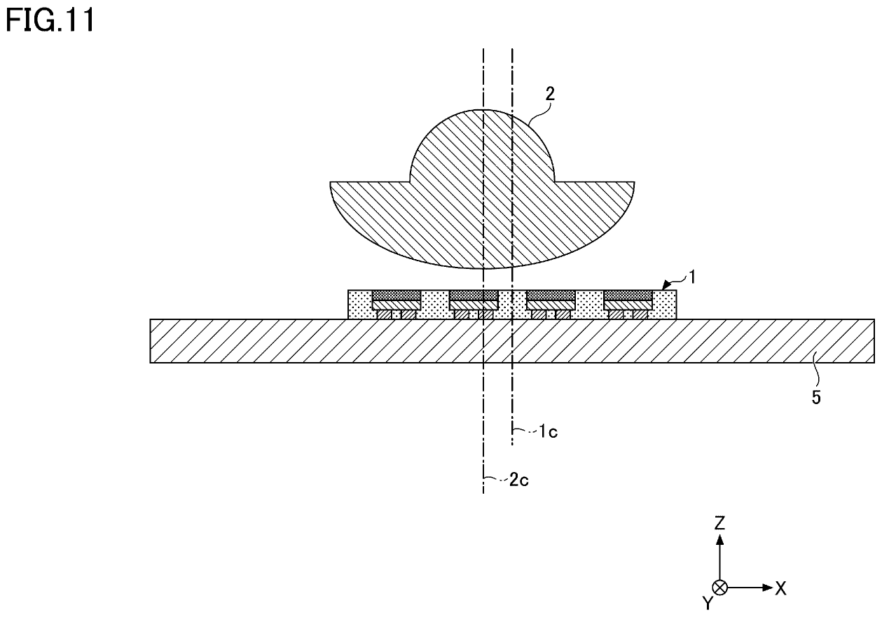

An operation of the light-emitting device 100 will be described with reference to FIGS. 10 to 27. FIG. 10 is a plan view illustrating a state in which the first lens 2 has moved to the −X and −Y direction sides with respect to the center axis 1c of the array light source 1 in the light-emitting device 100. FIG. 11 is a cross-sectional view taken along XA-XA in FIG. 10.

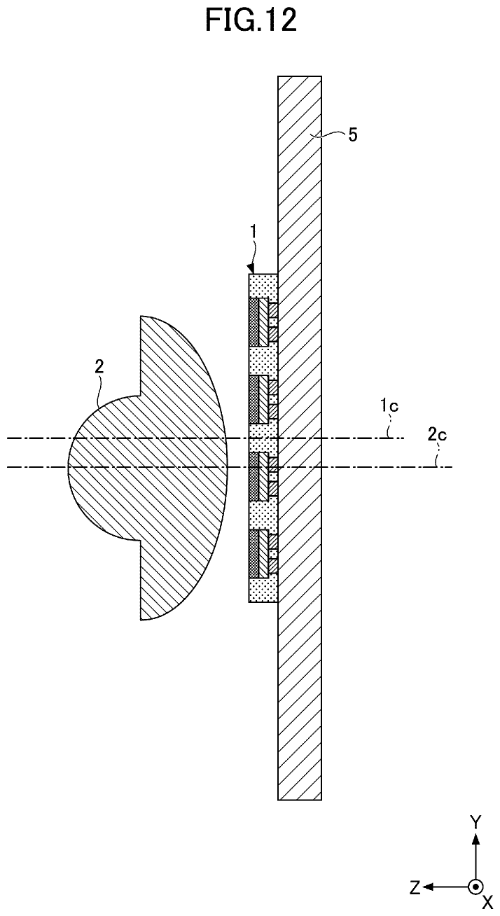

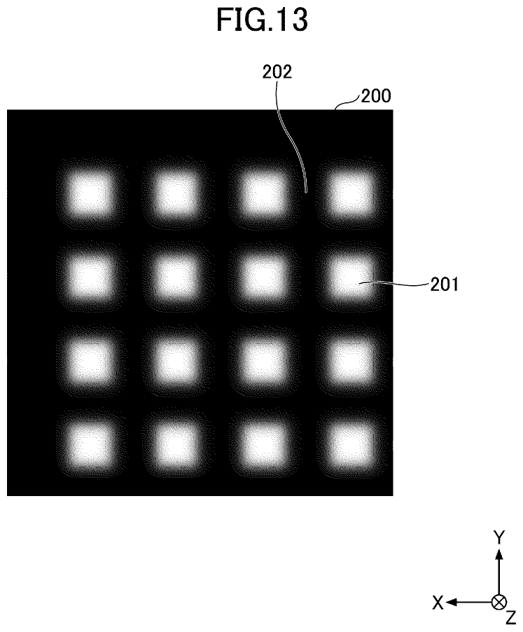

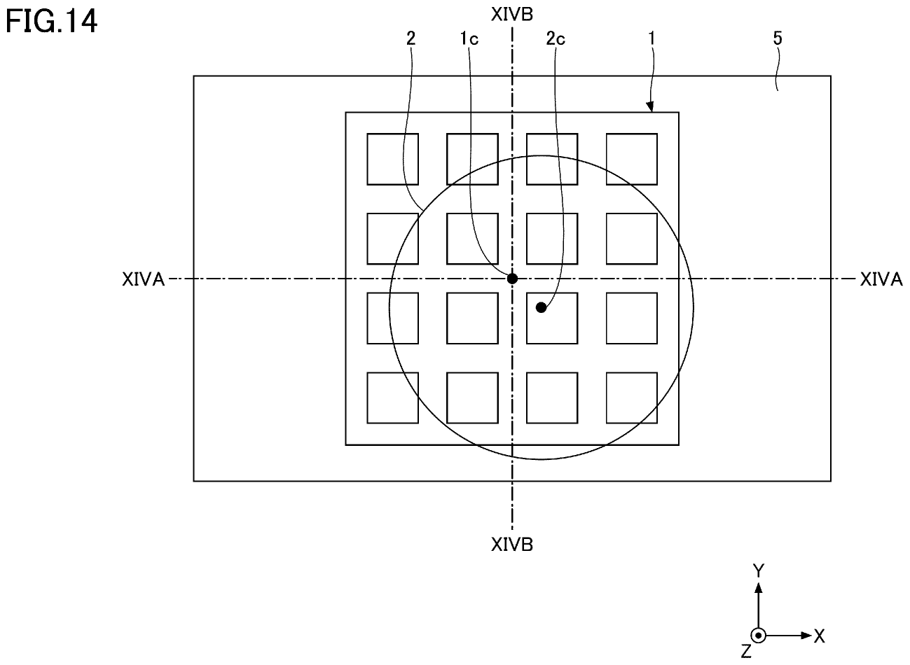

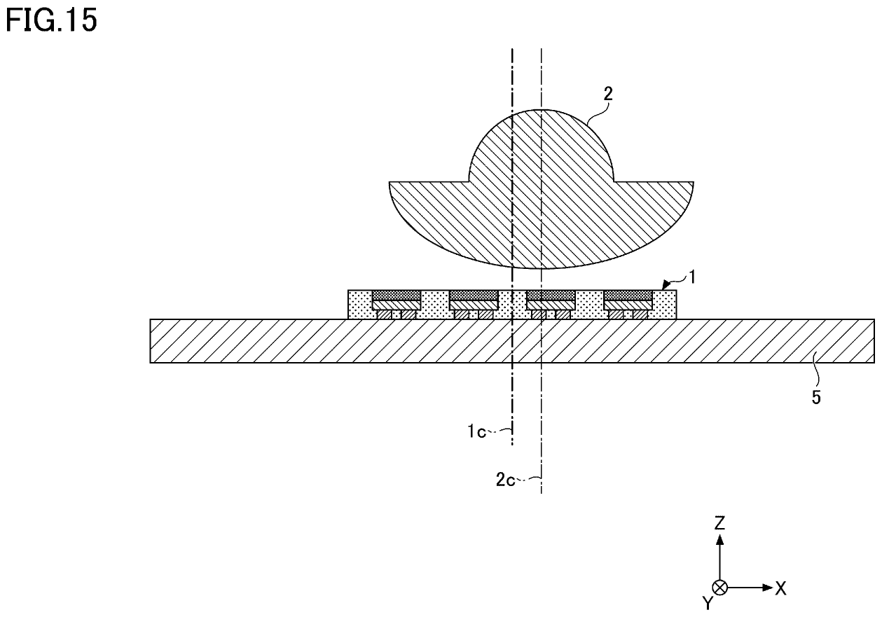

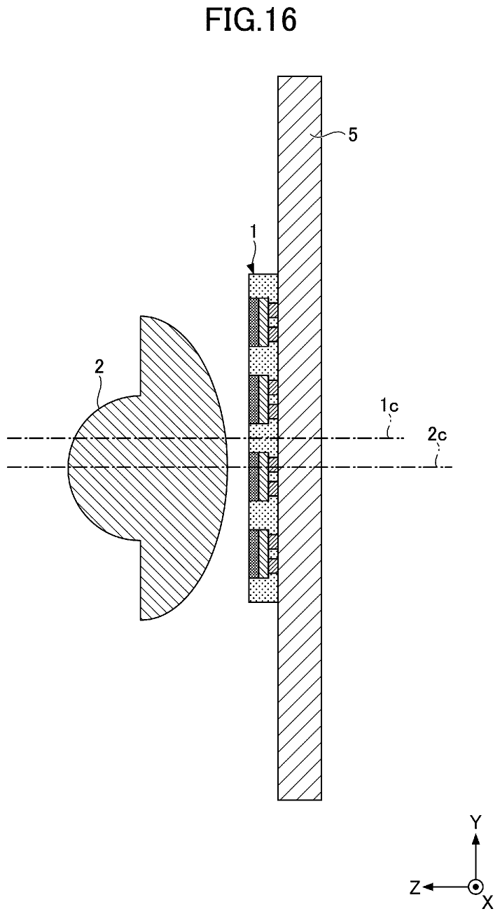

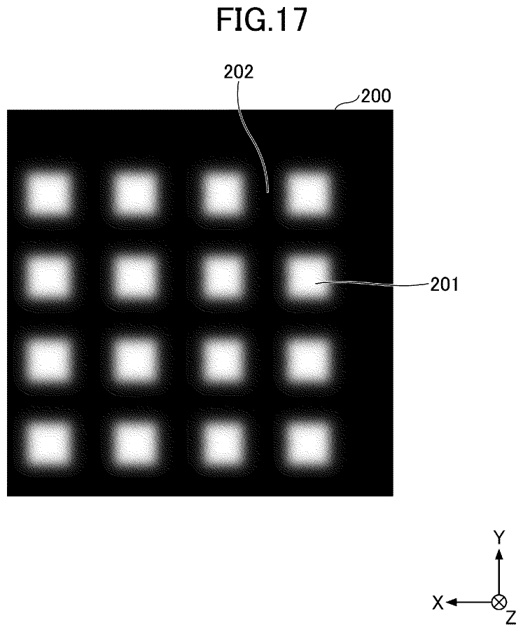

FIG. 12 is a cross-sectional view taken along XB-XB in FIG. 10. FIG. 13 is a diagram illustrating an example of irradiation light when the light-emitting device 100 is in the state of FIG. 10. FIG. 14 is a plan view illustrating a state in which the first lens 2 has moved to the +X and −Y direction sides with respect to the center axis 1c of the array light source 1 in the light-emitting device 100. FIG. 15 is a cross-sectional view taken along XIVA-XIVA in FIG. 14. FIG. 16 is a cross-sectional view taken along XIVB-XIVB in FIG. 14. FIG. 17 is a diagram illustrating an example of the irradiation light when the light-emitting device 100 is in the state of FIG. 14.

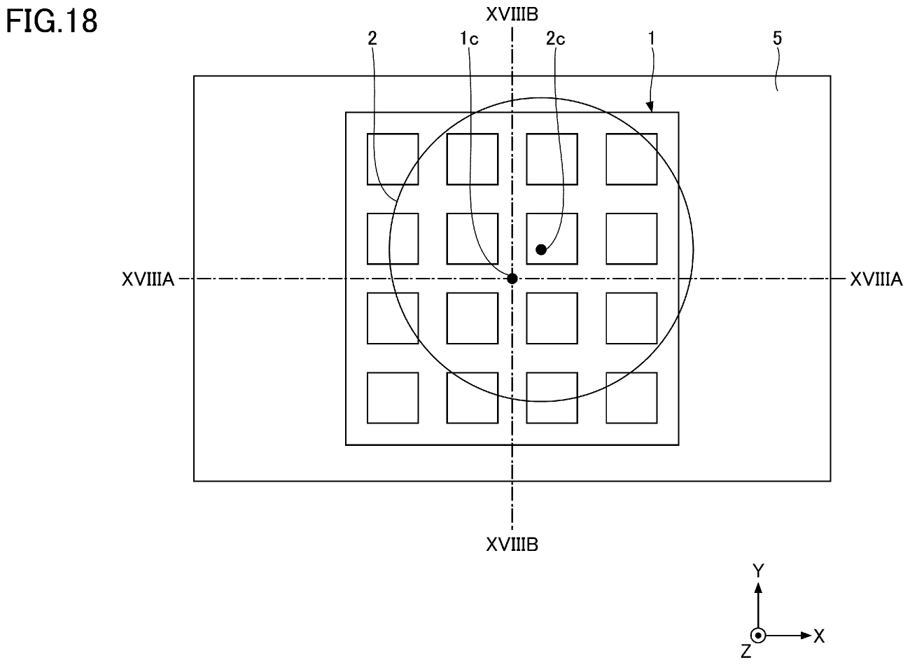

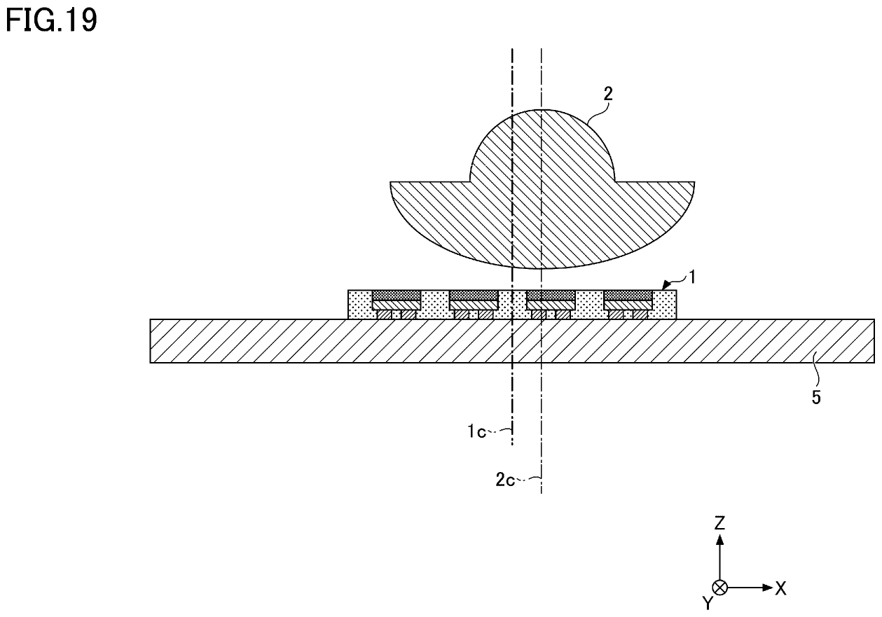

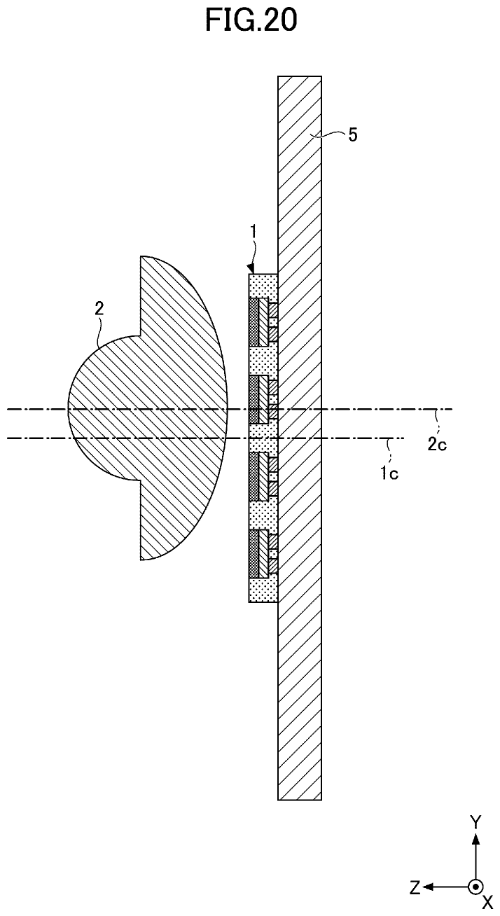

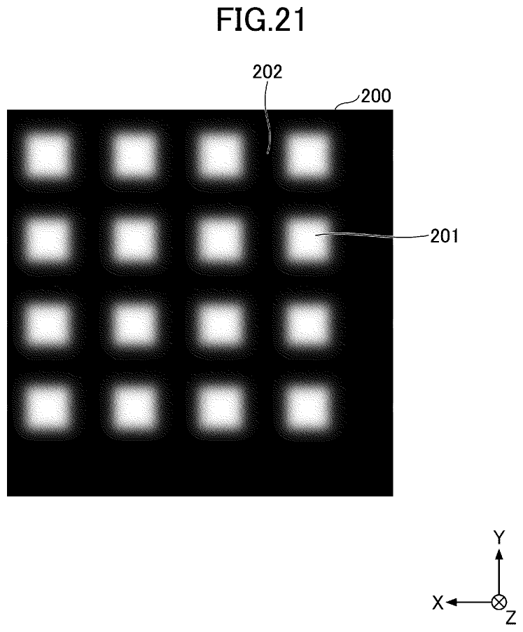

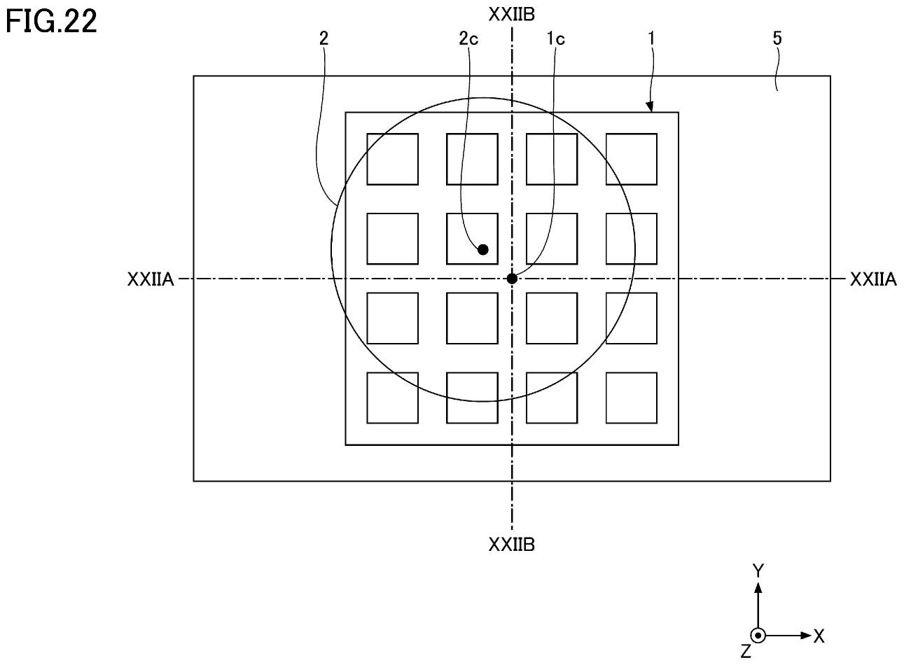

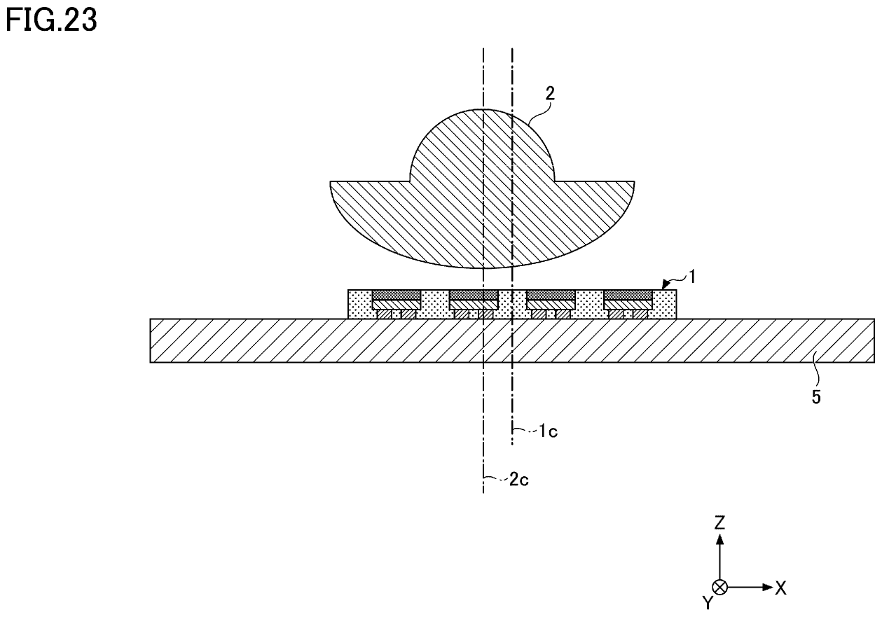

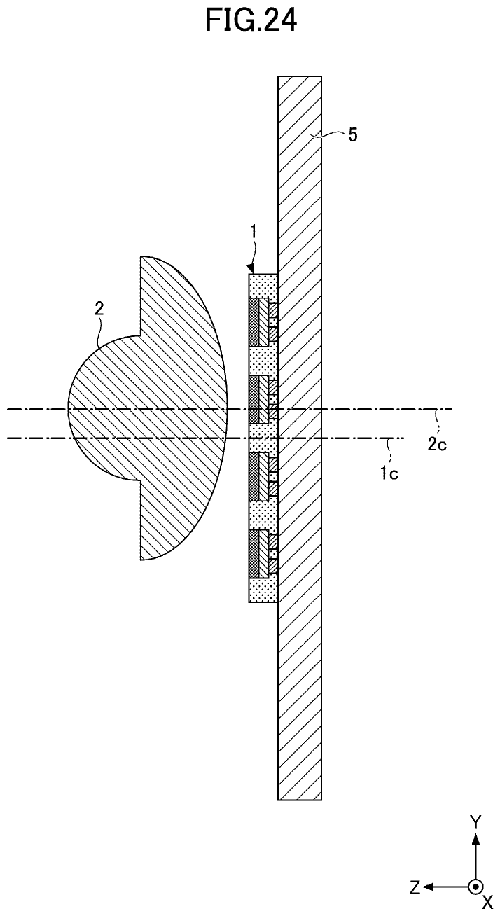

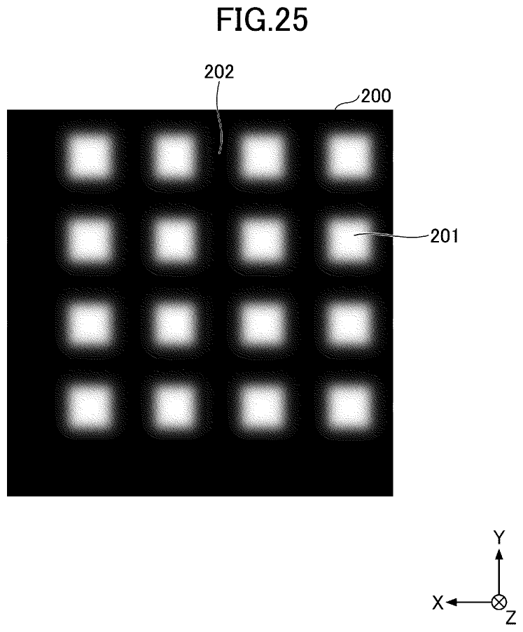

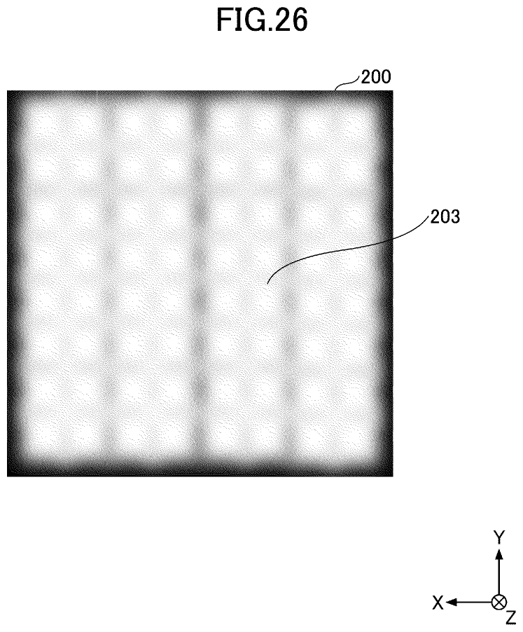

FIG. 18 is a plan view illustrating a state in which the first lens 2 has moved to the +X and +Y direction sides with respect to the center axis 1c of the array light source 1 in the light-emitting device 100. FIG. 19 is a cross-sectional view taken along XVIIIA-XVIIIA in FIG. 18. FIG. 20 is a cross-sectional view taken along XVIIIB-XVIIIB in FIG. 18. FIG. 21 is a diagram illustrating an example of the irradiation light when the light-emitting device 100 is in the state of FIG. 18. FIG. 22 is a plan view illustrating a state in which the first lens 2 has moved to the −X and +Y direction sides with respect to the center axis 1c of the array light source 1 in the light-emitting device 100. FIG. 23 is a cross-sectional view taken along XXIIA-XXIIA in FIG. 22. FIG. 24 is a cross-sectional view taken along XXIIB-XXIIB in FIG. 22. FIG. 25 is a diagram illustrating an example of the irradiation light when the light-emitting device 100 is in the state of FIG. 22. FIG. 26 is a diagram illustrating an exemplary synthesis of the irradiation light in FIGS. 13, 17, 21, and 25.

In FIGS. 10 to 12, 14 to 16, 18 to 20, and 22 to 24, the first lens 2, the array light source 1, and the light-emitting unit mounting substrate 5 of the light-emitting device 100 are illustrated in order to indicate the positional relationship between the first lens 2 and the array light source 1. Further, the array light source 1 is illustrated through the first lens 2.

FIGS. 13, 17, 21, and 25 illustrate 16 irradiation light beams 201 obtained in the region to be irradiated 200 in the direction in which an object is viewed from the light-emitting device 100 side when all of 16 light-emitting units 10 emit light.

Light is not emitted from regions other than the region in which the light-emitting unit 10 is provided in the array light source 1, and thus a dark portion 202, which is a low illuminance region, is generated between the irradiation light beams 201.

In FIGS. 10 to 12, regarding the first lens 2, the optical axis 2c of the first lens 2 is moved to the −X side and the −Y side with respect to the center axis 1c of the array light source 1. This state is referred to as a first state. In the first state, as illustrated in FIG. 13, respective positions of the 16 irradiation light beams 201 in the region to be irradiated 200 move to the −X side and the −Y side in accordance with the position of the first lens 2.

The position at which the light-emitting unit 10 is disposed and the position of the irradiation light 201 in the region to be irradiated 200 (irradiation position of light emitted by the light-emitting unit 10 by the first lens 2) are in a point-symmetrical positional relationship with respect to the optical axis 2c (optical center) of the first lens 2 serving as the center of symmetry.

In FIGS. 14 to 16, the first lens 2 is moved such that the optical axis 2c of the first lens 2 is shifted to the +X side and the −Y side with respect to the center axis 1c of the array light source 1. This state is referred to as a second state. In the second state, as illustrated in FIG. 17, the respective positions of the 16 irradiation light beams 201 in the region to be irradiated 200 move to the +X side and the −Y side in accordance with the movement of the first lens 2. The position at which the light-emitting unit 10 is disposed and the position of the irradiation light 201 in the region to be irradiated 200 are in a point-symmetrical positional relationship with respect to the optical axis 2c of the first lens 2 serving as the center of symmetry.

In FIGS. 18 to 20, the first lens 2 moves such that the optical axis 2c of the first lens 2 is shifted to the +X side and the +Y side with respect to the center axis 1c of the array light source 1. This state is referred to as a third state. In the third state, as illustrated in FIG. 21, the positions of the respective 16 irradiation light beams 201 in the region to be irradiated 200 move to the +X side and the +Y side in accordance with the movement of the first lens 2. The position at which the light-emitting unit 10 is disposed and the position of the irradiation light 201 in the region to be irradiated 200 are in a point-symmetrical positional relationship with respect to the optical axis 2c of the first lens 2 as the center of symmetry.

In FIGS. 22 to 24, the first lens 2 moves such that the optical axis 2c of the first lens 2 is shifted to the −X side and the +Y side with respect to the center axis 1c of the array light source 1. This state is referred to as a fourth state. In the fourth state, as illustrated in FIG. 25, the positions of the respective 16 irradiation light beams 201 in the region to be irradiated 200 move to the −X side and the +Y side in accordance with the movement of the first lens 2. The position at which the light-emitting unit 10 is disposed and the position of the irradiation light 201 in the region to be irradiated 200 are in a point-symmetrical positional relationship with respect to the optical axis 2c of the first lens 2 serving as the center of symmetry.

In the present embodiment, the first lens 2 relatively moves in the order of the first state, the second state, the third state, and the fourth state, returns to the first state again after becoming the fourth state, and then in the order of the second state and the third state to repeat the movement. That is, the light-emitting device 100 repeatedly performs a round-trip movement in which one cycle starts from the first state and returns to the first state.

The distance of the first relative movement along the X direction in each of a movement from the first state to the second state, a movement from the second state to the third state, a movement from the third state to the fourth state, and a movement from the fourth state to the first state is equal to or greater than the length of the first light-emitting surface interval dx. The distance of the second relative movement along the Y direction is equal to or greater than the length of the second light-emitting surface interval dy. As an example, in the present embodiment, the distance of the first relative movement is substantially equal to the length of the first light-emitting surface interval dx, and the distance of the second relative movement is substantially equal to the length of the second light-emitting surface interval dy.

In the light-emitting device 100, by causing the light-emitting unit 10 to emit light while performing a relative round-trip movement of the first lens 2 within the exposure period, as illustrated in FIG. 26, the respective irradiation light beams 201 of FIGS. 13, 17, 21, and 25 can be combined to obtain a combined light 203 in which the illuminance of the dark portion 202 in the region to be irradiated 200 is compensated. In other words, the control unit 4 can control the relative movement by the movement mechanism 3 so as to compensate for the illuminance of the region corresponding to the first light-emitting surface interval dx in the region to be irradiated 200. Similarly, the control unit 4 can control the relative movement by the movement mechanism 3 so as to compensate for the illuminance of the region corresponding to the second light-emitting surface interval dy in the region to be irradiated 200. Here, the configuration in which the first lens 2 performs the relative round-trip movement has been exemplified.

However, the relative movement of the first lens 2 need not necessarily be the round-trip movement. For example, the light-emitting device 100 may store the position information of the first lens 2 after the relative movement of the first lens 2, and start the subsequent relative movement of the first lens 2 using the position indicated by the stored position information as the start position.

FIG. 26 illustrates a case in which all of the 16 light-emitting units 10 are caused to emit light during the entire period of the exposure period to irradiate the entirety of the region to be irradiated 200. The state illustrated in FIG. 26 is equivalent to the state in which the combined light 203 is emitted onto the region to be irradiated 200 in the exposure period of the imaging device In the state illustrated in FIG. 26, the division number of 4×4=16 of the region to be irradiated 200 by the 16 light-emitting units 10 is pseudo-increased to the division number of 8×8=64. The light-emitting device 100 can perform partial irradiation by selecting a light-emitting unit 10 to be caused to emit light from among the plurality of light-emitting units 10 and a period to emit light from within the exposure period and switching between irradiation and non-irradiation for each of 64 regions obtained by dividing the region to be irradiated 200.

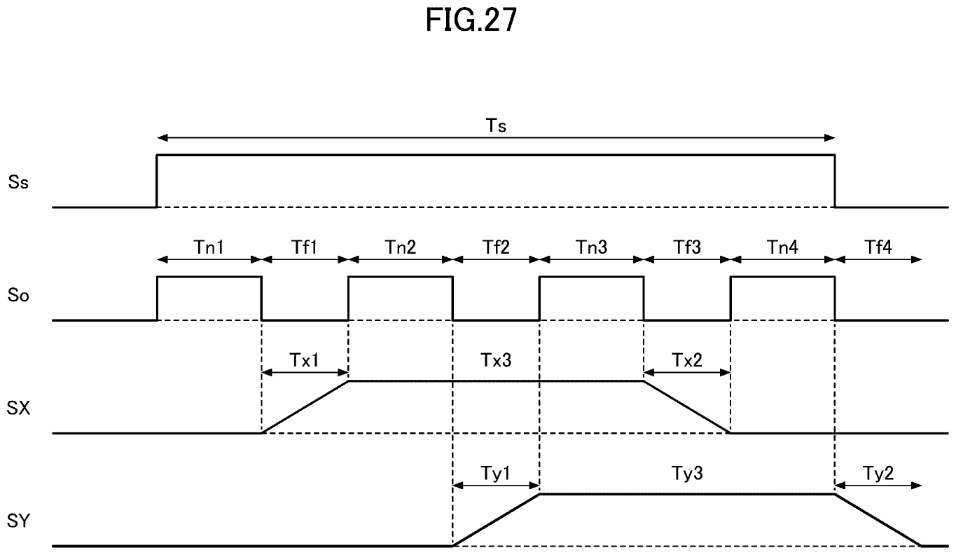

FIG. 27 is a timing chart exemplifying the operation of the light-emitting device 100. FIG. 27 indicates an exposure signal Ss indicating an exposure timing of the imaging device on which the light-emitting device 100 is mounted, and a light emission signal So indicating a light emission timing of the light-emitting unit 10. FIG. 27 also indicates an X position signal SX indicating the position of the first lens 2 in the X direction and a Y position signal SY indicating the position of the first lens 2 in the Y direction. The vertical axis of the exposure signal Ss in FIG. 27 indicates an OFF state and an ON state. The vertical axis of the light emission signal So in FIG. 27 is a voltage. In FIG. 27, the vertical axis of the X position signal SX and the vertical axis of the Y position signal SY indicate relative positions.

In FIG. 27, it is assumed that all of the 16 light-emitting units 10 perform the same operation. However, the 16 light-emitting units 10 need not perform the same operation, and can operate independently from one another.

An exposure period Ts is a period during which an electronic shutter of the imaging device is opened. The exposure period Ts is, for example, 1/30 [sec] or 1/60 [sec]. The electronic shutter is opened at the timing when the exposure signal Ss has entered the ON state, and the electronic shutter is closed at the timing when the exposure signal Ss has entered the OFF state.

Light emission periods Tn1, Tn2, Tn3, and Tn4 are periods during which the light-emitting unit 10 emits light (in other words, lights up). Non-light emission periods Tf1, Tf2, Tf3, and Tf4 are periods in which the light-emitting unit 10 does not emit light (in other words, is turned off). The light-emitting unit 10 emits light at the timing when the light emission signal So has entered the ON state, and the light-emitting unit 10 does not emit light at the timing when the light emission signal So has entered the OFF state.

In moving periods Tx1 and Tx2, the X position signal SX changes with time. The moving periods Tx1 and Tx2 are periods during which the first lens 2 moves along the X direction by the movement mechanism 3. The first lens 2 moves in the +X direction in the moving period Tx1, and the first lens 2 moves in the −X direction in the moving period Tx2. In a stopping period Tx3, the X position signal SX is constant, and the first lens 2 is stopped in the X direction. The movement in the moving period Tx1 corresponds to the movement of the first lens 2 from the first state to the second state, and the movement in the moving period Tx2 corresponds to the movement of the first lens 2 from the third state to the fourth state.

In moving periods Ty1 and Ty2, the Y position signal SY changes with time. The moving periods Ty1 and Ty2 are periods during which the first lens 2 moves along the Y direction by the movement mechanism 3. The first lens 2 moves in the +Y direction in the moving period Ty1, and the first lens 2 moves in the −Y direction in the moving period Ty2. In a stopping period Ty3, the Y position signal SY is constant. The stopping period Ty3 is a period during which the first lens 2 is stopped in the Y direction. The movement in the moving period Ty1 corresponds to the movement of the first lens 2 from the second state to the third state, and the movement in the moving period Ty2 corresponds to the movement of the first lens 2 from the fourth state to the first state.

When the exposure period Ts is started in response to the acquirement of timing information from the smartphone by the timing acquisition unit 43, first, in the light emission period Tn1, in the light-emitting device 100, the light emission control unit 41 causes the light-emitting unit 10 to emit light. In this period, the state of the first lens 2 is the first state, and the first lens 2 is stopped.

Subsequently, in the moving period Tx1, in the light-emitting device 100, the movement control unit 42 causes the first lens 2 to move in the +X direction by a distance substantially equal to the first light-emitting surface interval dx. In the non-light emission period Tf1 parallel to the moving period Tx1, in the light-emitting device 100, the light emission control unit 41 causes the light-emitting unit 10 to not emit light. The first lens 2 stops after moving in the +X direction by a distance substantially equal to the first light-emitting surface interval dx.

Subsequently, in the light emission period Tn2, in the light-emitting device 100, the light emission control unit 41 causes the light-emitting unit 10 to emit light. In this period, the state of the first lens 2 is the second state, and the first lens 2 is stopped.

Subsequently, in the moving period Ty1, in the light-emitting device 100, the movement control unit 42 causes the first lens 2 to move in the +Y direction by the second light-emitting surface interval dy. In the non-light emission period Tf2 parallel to the moving period Ty1, in the light-emitting device 100, the light emission control unit 41 causes the light-emitting unit 10 to not emit light. The first lens 2 stops after moving in the +Y direction by a distance substantially equal to the second light-emitting surface interval dy.

Subsequently, in the light emission period Tn3, in the light-emitting device 100, the light emission control unit 41 causes the light-emitting unit 10. In this period, the state of the first lens 2 is the third state, and the first lens 2 is stopped.

Subsequently, in the moving period Tx2, in the light-emitting device 100, the movement control unit 42 causes the first lens 2 to move in the −X direction by a distance substantially equal to the first light-emitting surface interval dx. In the non-light emission period Tf3 parallel to the moving period Tx2, in the light-emitting device 100, the light emission control unit 41 causes the light-emitting unit 10 to not emit light. The first lens 2 stops after moving in the −X direction by a distance substantially equal to the first light-emitting surface interval dx.

Subsequently, in the light emission period Tn4, in the light-emitting device 100, the light emission control unit 41 causes the light-emitting unit 10 to emit light. In this period, the state of the first lens 2 is the fourth state, and the first lens 2 is stopped.

Subsequently, in the moving period Ty2, in the light-emitting device 100, the movement control unit 42 causes the first lens 2 to move in the −Y direction by a distance substantially equal to the second light-emitting surface interval dy. In the non-light emission period Tf4 parallel to the moving period Ty2, in the light-emitting device 100, the light emission control unit 41 causes the light-emitting unit 10 to not emit light. The first lens 2 stops after moving in the −Y direction by a distance substantially equal to the second light-emitting surface interval dy.

In this way, in the light-emitting device 100, an intermittent relative movement can be performed four times in total as one cycle of a round-trip movement within the exposure period Ts. Intermittent relative movements refer to relative movements that are performed or stopped at predetermined time intervals. The light emission control unit 41 performs control such that each of the plurality of light-emitting units 10 does not emit light in the moving periods Tx1, Tx2, Ty1, and Ty2 in each of which the first lens 2 performs one intermittent relative movement. The light-emitting device 100 may perform two or more cycles of the round-trip movement within the exposure period Ts.

In the present embodiment, the first lens 2 is caused to relatively move in a state in which the light-emitting unit 10 does not emit light.

However, in the light-emitting device 100, the first lens 2 can be caused to relatively move in a state in which the light-emitting unit 10 emits light. By eliminating the non-light emission period of the light-emitting unit 10 as described above, the light amount of the irradiation light of the light-emitting device 100 can be increased.

### Action and Effect of Light-Emitting Device 100

As described above, the light-emitting device 100 includes the array light source 1 including the plurality of light-emitting units 10 arranged in an array pattern, and the first lens 2 that irradiates the region to be irradiated 200 with light emitted by the array light source 1. The light-emitting device 100 can partially irradiate a desired region in the region to be irradiated 200, which can be irradiated with light by the light-emitting device 100 itself, with light and change the partial irradiation region by switching the light-emitting unit 10 that emits light among the plurality of light-emitting units 10.

In such partial irradiation, the larger the number of divisions of the region to be irradiated is, the more natural partial irradiation light can be obtained, which is preferable. However, the space of the light-emitting device itself in the imaging device is limited, the interval between the plurality of light-emitting units that are mountable is limited, and therefore the number of light-emitting units that are mountable on the light-emitting device and the number of divisions of the region to be irradiated are limited in some cases.

For example, the limit of each of the first light-emitting surface interval dx and the second light-emitting surface interval dy is set to 0.1 [mm], and the size of the array light source 1 in a plan view is set to 1.0×1.0 [mm]. When the number of the light-emitting units 10 is simply increased to increase the number of divisions, the relationship between the number of divisions of the region to be irradiated 200 and the widths Wx and Wy of the light-emitting surface 11 is as shown in Table 1 below.

TABLE 1

| | Number of divisions (regions) | | | |
|---|---|---|---|---|
| | 2 × 2 = 4 | 4 × 4 = 16 | 6 × 6 = 36 | 10 × 10 = 100 |
| Width of light- | 0.4 × 0.4 | 0.15 × 0.15 | 0.07 × 0.07 | 0.001 × 0.001 |
| emitting | | | | |
| surface | | | | |
| Wx × Wy | | | | |
| (mm) | | | | |

As shown in Table 1, if the number of the light-emitting units 10 itself is increased to increase the number of divisions of the region to be irradiated, the individual light-emitting units 10 decrease in size. As a result, in addition to decrease in the light amount of each light-emitting unit 10, the area of the electrode included in the light-emitting unit 10 decreases. Moreover, if the number of divisions of the region to be irradiated is increased without reducing the size of the light-emitting unit 10, the size of the entire light-emitting device 100 increase.

In the present embodiment, the light-emitting device 100 includes the movement mechanism 3 configured to cause the first lens 2 and the array light source 1 to move relative to each other along a direction intersecting with the optical axis 2c of the first lens 2. The light-emitting device 100 also includes the control unit 4 including the light emission control unit 41 that controls light emission of each of the plurality of light-emitting units 10 and the movement control unit 42 that controls the operation of the movement mechanism 3.

The light emission control unit 41 is configured to control the light emission of each of the plurality of light-emitting units 10 within the exposure period Ts (predetermined period), and the movement control unit 42 is configured to control the operation of the movement mechanism 3 such that the first lens 2 and the array light source 1 perform the relative movement within the exposure period Ts. The relative movement includes a first relative movement in which the first lens 2 and the array light source 1 move relative to each other along the X direction (first direction). Each of the plurality of light-emitting units 10 has the light-emitting surface 11, and the light-emitting surfaces 11 of adjacent ones of light-emitting units 10 are located at the first light-emitting surface interval dx therebetween. The distance of the first relative movement is equal to or greater than the length of the shorter one of either the first light-emitting surface interval dx or the width Wx of the light-emitting surface 11 along the X direction.

With this configuration, it is possible to increase the number of the light-emitting units 10 in a pseudo manner in light irradiation within the exposure period Ts. The number of light-emitting units 10 is not increased to the limit for the purpose of increasing the number of divisions of the region to be irradiated 200, which can inhibit decrease in size of the individual light-emitting units 10. Therefore, it is possible to inhibit difficulty in the mounting and decrease in mass-productivity and reliability of the array light source 1. In addition, pseudo-increase in the number of divisions allows for inhibiting an increase in the size of the array light source 1 or the entire light-emitting device 100. Accordingly, it is possible to provide the light-emitting device 100 that can control a region to be partially irradiated with light in the region to be irradiated 200. Further, natural partial irradiation light can be obtained by increasing the number of divisions of the region to be irradiated 200.

Further, in the present embodiment, the plurality of light-emitting units 10 are arranged along the X direction or disposed along the X direction and the Y direction (second direction). With this configuration, partial irradiation can be performed two dimensionally in the region to be irradiated 200.

Further, in the present embodiment, the control unit 4 performs control so as to compensate for the illuminance of the region corresponding to the first light-emitting surface interval dx in the region to be irradiated 200. By this control, the light-emitting device 100 can perform partial irradiation while reducing the dark portion 202 corresponding to the first light-emitting surface interval dx in the region to be irradiated 200, and can increase the number of divisions of the region to be irradiated 200 while avoiding illuminance unevenness in the region to be irradiated 200.

The first light-emitting surface interval dx is preferably in a range from 0.05 [mm] to 2.00 [mm]. Accordingly, it is possible to achieve both of obtaining good light emission characteristics and an interval at which the plurality of light-emitting units 10 are mountable, and it is possible to increase the number of divisions of the region to be irradiated 200 under conditions in which the light-emitting unit 10 can be easily mounted.

Further, in the present embodiment, the relative movement by the movement mechanism 3 further includes the second relative movement in which the first lens 2 and the array light source 1 move relative to each other along the Y direction orthogonal to the X direction. The light-emitting surfaces 11 of adjacent light-emitting units 10 are arranged along the Y direction at the second light-emitting surface interval dy, and the distance of the second relative movement is equal to or greater than the length of the shorter one of either the second light-emitting surface interval dy or the width Wy of the light-emitting surface 11 along the Y direction. With this configuration, it is possible to pseudo-increase the number of the light-emitting units 10 in both directions of the X and Y directions in light irradiation within the exposure period Ts.

Accordingly, it is possible to provide the light-emitting device 100 that can more precisely control the region to be partially irradiated with light in the region to be irradiated 200.

Further, in the present embodiment, the relative movement by the movement mechanism 3 is an intermittent relative movement that is performed four times. The light emission control unit 41 performs control such that each of the plurality of light-emitting units 10 does not emit light while performing a single intermittent relative movement.

If light is emitted from the light-emitting unit 10 while the first lens 2 is relatively moving, the irradiation light 201 moves on the region to be irradiated 200 in accordance with the relative movement, and thus illuminance variation, such as flickering, of the irradiation light 201 or the combined light 203, occurs in some cases. In the light-emitting device 100, performing control such that each of the plurality of light-emitting units 10 does not emit light while performing a single intermittent relative movement allows for reducing a change in illuminance in the region to be irradiated due to the relative movement. In addition, by providing a time during which the light-emitting unit 10 does not emit light, heat generation by the light-emitting unit 10 can be reduced. The number of times of the intermittent relative movement is not limited to four, and can be adjusted as appropriate according to the settings of the first light-emitting surface interval dx, the second light-emitting surface interval dy, and the like.

Further, in the present embodiment, the light emission control unit 41 controls switching of a light-emitting unit that emits light among the 16 light-emitting units 10 and/or the intensity of light emitted by the light-emitting unit 10. By performing this control, the irradiation position of light can be controlled without increasing the number of the light-emitting units 10.

Further, in the present embodiment, the position at which the light-emitting unit 10 is disposed and the irradiation position of light emitted by the light-emitting unit 10 by the first lens 2 are in a point-symmetrical positional relationship with respect to the optical axis 2c (optical center) of the first lens 2 as the center of symmetry. With this configuration, when the first lens 2 is accommodated inside the housing 6, in the light-emitting device 100, light from the light-emitting unit 10 can be inhibited from being shaded by the housing 6.

### Second Embodiment

A light-emitting device 100a according to a second embodiment will be described. Members having the same terms and reference signs as the first embodiment represent the same members or members of the same quality, and a detailed description of these members will be omitted as appropriate. This is also true for the embodiments described below.

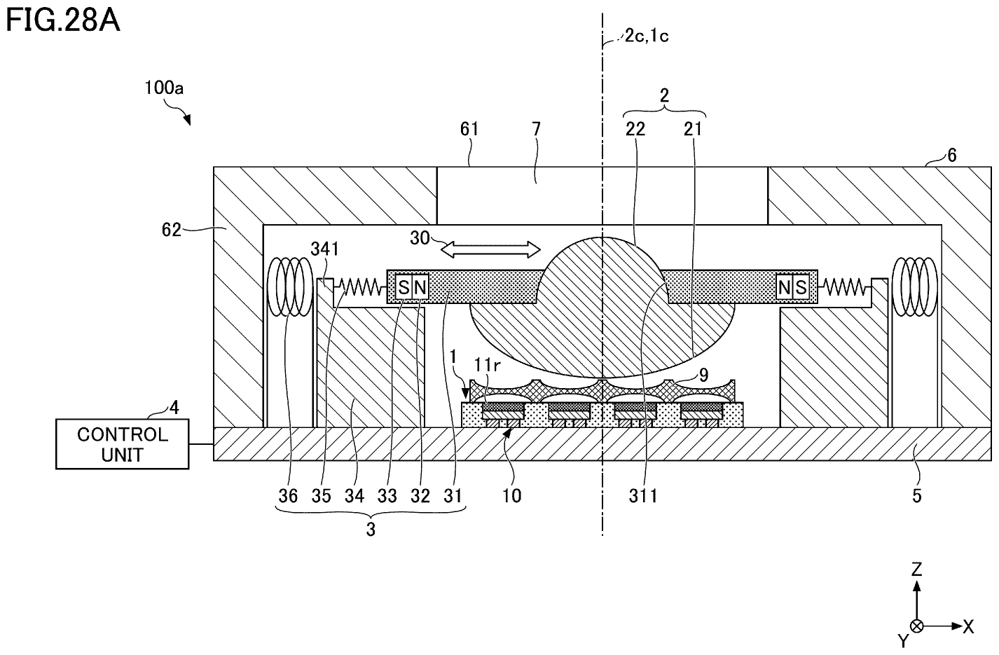

FIG. 28A is a cross-sectional view illustrating an example of a configuration of the light-emitting device 100a. The light-emitting device 100a includes 16 second lenses 9 arranged in pairs with respective ones of the 16 light-emitting units 10. The 16 second lenses 9 are provided between the first lens 2 and the array light source 1. The 16 second lenses 9 arranged in an array pattern are connected across the light-emitting units 10 to be formed as a single body.

The 16 second lenses 9 has the same shape, and each of the 16 second lenses 9 is a single biconcave lens (hereinafter referred to as a biconcave lens) in which both the array light source 1 side and the side opposite to the array light source 1 (first lens 2 side) thereof are concave surfaces. The 16 second lenses 9 may be spaced apart and independent from each other.

The second lens 9 is optically transmissive to light emitted by the light-emitting unit 10 and includes a resin material, such as polycarbonate resin, acrylic resin, silicone resin, epoxy resin, or the like, and/or a glass material.

FIG. 28B is a diagram for describing light rays when the second lens 9 is a concave lens. In FIG. 28B, a light ray 281 represents a light ray passing through a center 2p of the first lens 2, the second lens 9, and a point 284. A virtual light ray 282 represents a virtual light ray when assuming that the light ray passes through the center 2p of the first lens 2 and a point 283 but does not pass through the second lens 9. The point 283 represents a point at an end position of a light-emitting surface 11r, and the point 284 represents a point corresponding to a virtual image of the point 283 by the second lens 9. A distance h represents the distance from the point 283 to the optical axis 2c, and a distance h′ represents the distance from the point 284 to the optical axis 2c. The angle θₕ represents an angle formed by the virtual light ray 282 and the optical axis 2c. θ_{h′} represents an angle formed by the light ray 281 and the optical axis 2c. F1 represents a focal point of the first lens 2. F1′ represents a virtual focal point of the first lens 2 when assuming the light ray does not pass through the second lens 9. In FIG. 28B, when the first lens 2 is caused to move by a predetermined distance in the −Z direction, the focal point F1 and the virtual focal point F1′ overlap with each other. F2 represents a focal point of the second lens 9.

In the light-emitting device 100a, the relationship between the angle θₕ and the angle θ_{h′} can be expressed by the following formula.

tanθ_{h′}<tanθₕ

θ_{h′}<θₕ

Here, it is preferable that 0°<θₕ<90° and 2°≤θₕ≤15°. It is also preferable that 0°<θ_{h′}<90° and 2°≤θ_{h′}≤15°.

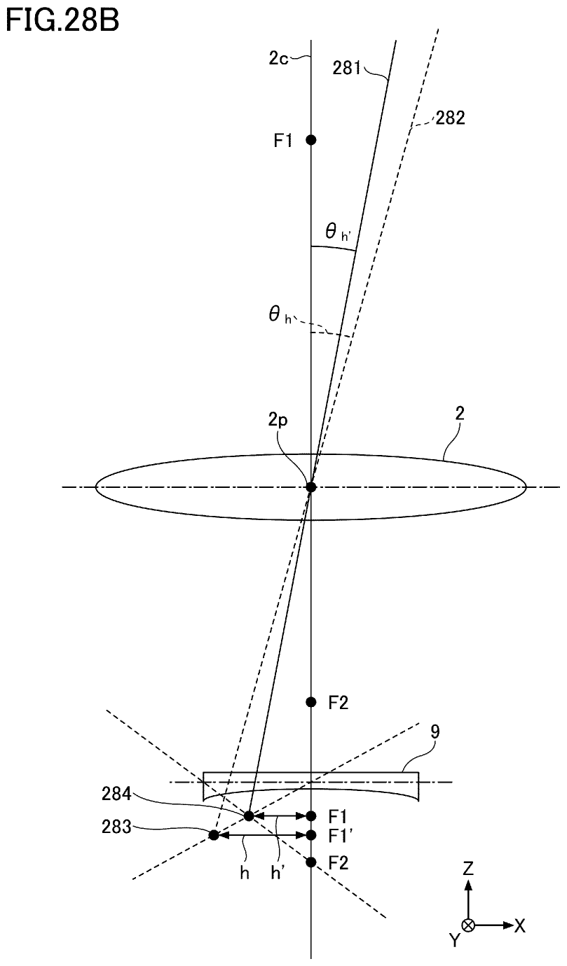

In the light-emitting device 100a, the area of the light-emitting surface 11r is apparently reduced by the action of the second lens 9, as illustrated in FIG. 29, on a region to be irradiated 200a, and thus the area of a light 201a emitted from each of the plurality of light-emitting surfaces 11r can be reduced. Thus, for example, even when the area of the light-emitting surface 11r is made larger than the area of the light-emitting surface 11 in the light-emitting device 100, the light beams 201a from the respective plurality of light-emitting surfaces 11r can be suppressed from overlapping with each other on the region to be irradiated 200a and illuminance unevenness can be suppressed. In addition, by increasing the area of the light-emitting surface 11r, it is possible to improve a pick-up performance, mounting performance, and the like of the light-emitting elements included in the array light source 1 in the manufacturing process. When a biconcave lens is used as the second lens 9, light controllability can be improved. In order to more suitably obtain the above-described action of the second lens 9, it is preferable to combine the first lens 2, which is a convex lens, and the second lens 9, which is a concave lens. Further, in order to particularly suitably obtain the above-described action of the second lens 9, the second lens 9 is preferably a biconcave lens. The advantageous effects other than those described above are similar to those in the first embodiment.

In addition, when a plano-concave lens having a flat surface on the array light source 1 side thereof and a concave surface on the first lens 2 side thereof is used as the second lens 9, the second lens 9 can be manufactured by integral-molding with the array light source 1, which is more preferable in terms of improving mass productivity of the light-emitting device 100a.

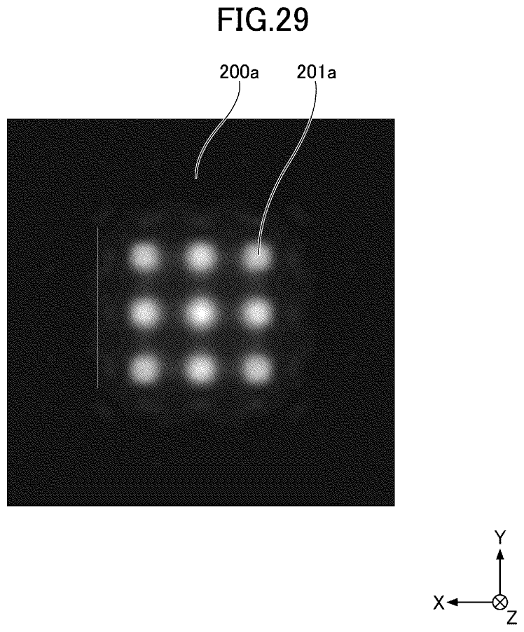

Here, FIG. 30 is a cross-sectional view illustrating a modified example of the array light source 1 of the light-emitting device 100a according to the second embodiment. As illustrated in FIG. 30, second lenses 9G are provided on the +Z side of an array light source 1G. Each second lens 9G is a single biconcave lens having a concave surface on the array light source 1G side, and having a concave surface on the side opposite to the array light source 1G. The second lens 9G forms a pair with a light-emitting unit 10G, and the plurality of second lenses 9G are integrally formed being connected between the light-emitting units 10G.

The second lens 9G causes light from a light-emitting surface 11Ga to irradiate the region to be irradiated 200. Due to the action of the second lens 9G, the light appears to be equivalent to being emitted from a light-emitting surface 11Gb having a width Wx7′ of a length shorter than the actual length of a width Wx7 of the light-emitting surface 11Ga.

In the array light source 1G, the length of the width Wx7′ of the apparent light-emitting surface 11Gb is shorter than the length of the width Wx7 of the light-emitting surface 11Ga. The length of the width Wx7′ of the light-emitting surface 11Gb is substantially equal to the length of the first light-emitting surface interval dx7. The length of the width Wx7 of the light-emitting surface 11Ga is longer than the length of the first light-emitting surface interval dx7. In this case, the distance of the first relative movement is substantially equal to or greater than the first light-emitting surface interval dx7. In other words, the distance of the first relative movement is equal to or greater than the length of the shorter one of either the first light-emitting surface interval dx7 or the width Wx7′ of the light-emitting surface 11Gb. The width Wx7 of the light-emitting surface 11Ga is equal to the width of a light-emitting element 12G.

Even in the light-emitting device 100a having the array light source 1G as described above, it is possible to control a region to be partially irradiated with light in the region to be irradiated 200, and to obtain natural partial irradiation light by increasing the number of divisions of the region to be irradiated 200.

### Modified Example of Second Lens 9

Hereinafter, various modified examples of the second lens 9 will be described.

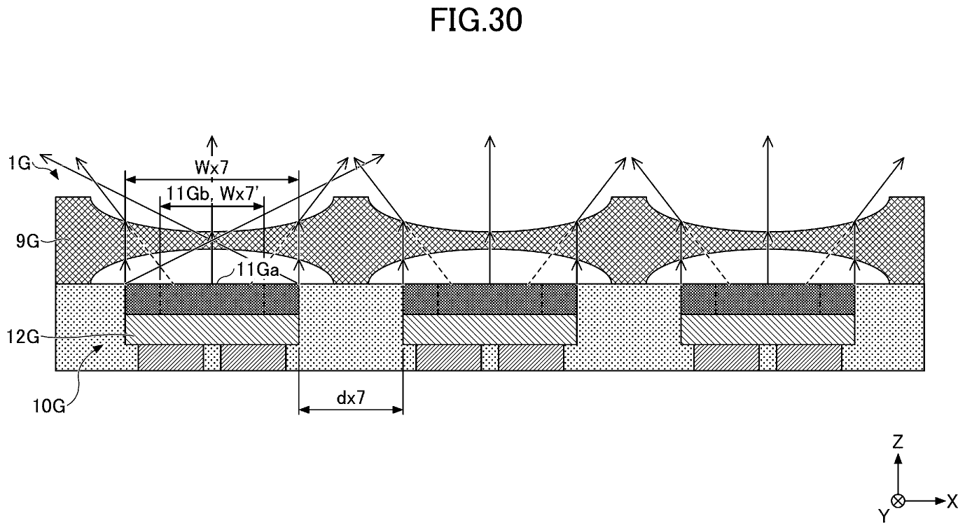

FIG. 31A is a cross-sectional view illustrating an example of a configuration of a light-emitting device 100aa including a second lens 9a according to a first modified example of the second embodiment.

As illustrated in FIG. 31A, each of the plurality of second lenses 9a has the same shape and is a single plano-convex lens with a surface on the array light source 1 side being a flat surface and a surface on the side opposite (first lens 2 side) to the array light source 1 being a convex surface.

Here, the number of the plurality of second lenses 9a is 16. The 16 second lenses 9a are spaced apart and independent from each other. As the material of the second lens 9a, a material that is the same as that of the second lens 9 described above can be applied. The 16 second lenses 9a arranged in an array pattern may be connected across the light-emitting units 10 to be formed as a single body.

FIG. 31B is a diagram for describing light rays when the second lens 9 is a convex lens. In FIG. 31B, a light ray 281a represents a light ray passing through the center 2p of the first lens 2, the second lens 9a, and a point 284a. A virtual light ray 282a represents a virtual light ray when assuming that the light ray passes through the center 2p of the first lens 2 and a point 283a, and does not pass through the second lens 9. The point 283a represents a point at an end position of the light-emitting surface 11, and the point 284a represents a point corresponding to a virtual image of the point 283a by the second lens 9. A distance ha represents the distance from the point 283a to the optical axis 2c, and ha′ represents the distance from the point 284a to the optical axis 2c. θₕₐ represents an angle formed by the virtual light ray 282a and the optical axis 2c. θ_{ha′} represents an angle formed by the light ray 281a and the optical axis 2c. Fla represents a focal point of the first lens 2. Fla′ represents a virtual focal point of the first lens 2 when assuming that the light ray does not pass through the second lens 9a. That, in FIG. 31B, when the first lens 2 is caused to move by a predetermined distance in the +Z direction, the focal point Fla and the virtual focal point Fla′ overlap each other. F2a represents a focal point of the second lens 9a.

In the light-emitting device 100aa, the relationship between the angle θₕₐ and the angle θ_{ha′} can be expressed by the following formula.

tanθ_{ha′}>tanθₕₐ

θ_{ha′}>θₕₐ

Here, it is preferable that 0°<θₕₐ<90° and 2°≤θₕₐ≤15°.
It is also preferable that 0°<θ_{ha′}<90° and 2°≤θ_{ha′}≤15°.

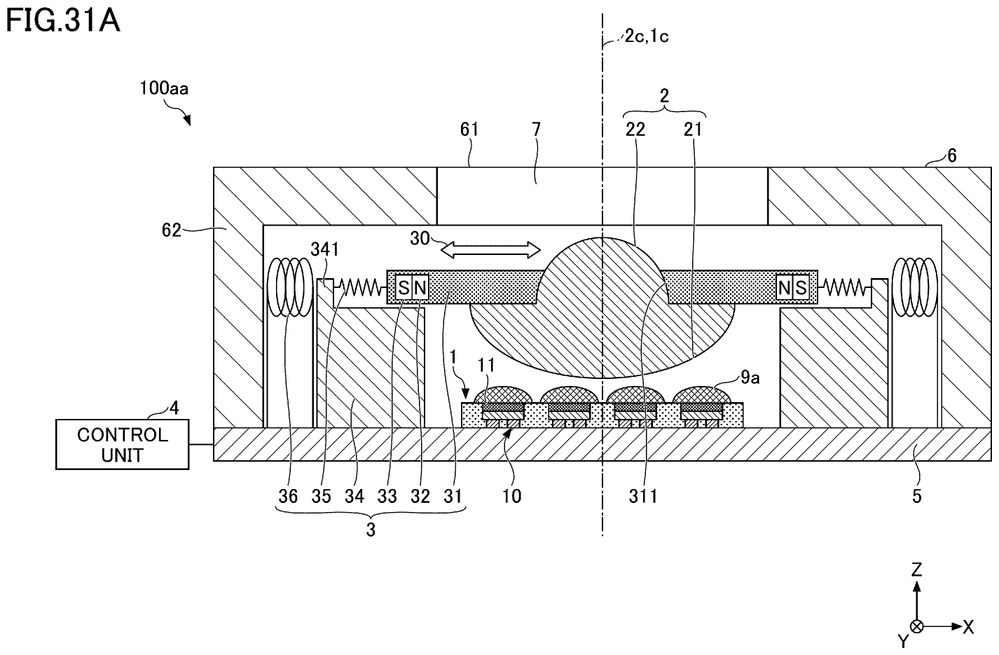

In the light-emitting device 100aa, the second lens 9a condenses light from the light-emitting surface 11. Alight 201aa condensed by the second lens 9a is emitted to a region to be irradiated 200aa by the first lens 2. That is, a light extraction efficiency can be improved by the second lens 9a. In the light-emitting device 100aa, as illustrated in FIG. 32, the light beams 201aa from the respective light-emitting surfaces 11 can be emitted so as to spread toward the region to be irradiated 200aa. Thus, the region partially irradiated by a single light-emitting surface 11 can be increased, so that the direction of the relative movement between the first lens 2 and the array light source 1 is not limited to the X direction or the Y direction and can be adjusted as appropriate. Accordingly, it is possible to provide the light-emitting device 100aa that can control a region to be partially irradiated with light in the region to be irradiated 200aa. The advantageous effects other than those described above are similar to those in the first embodiment.

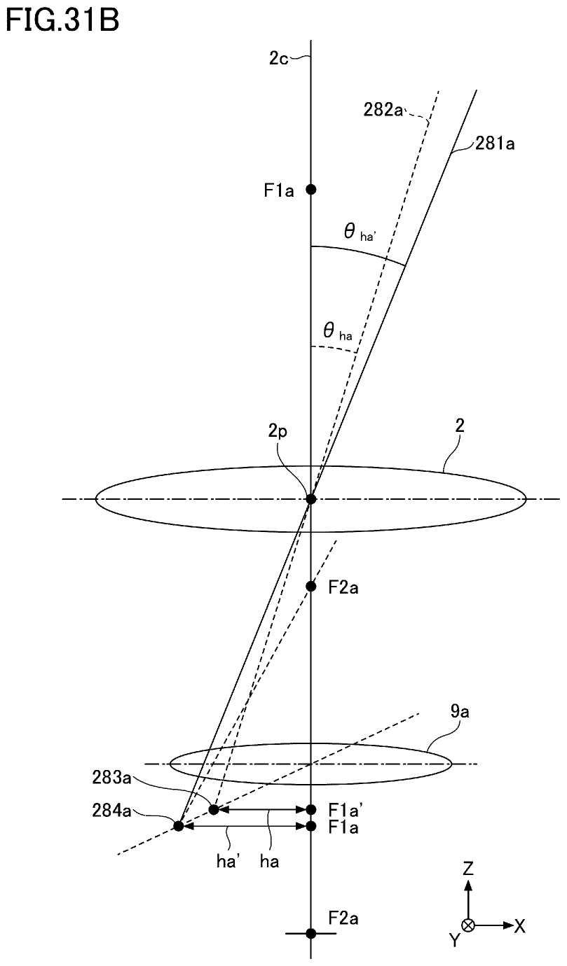

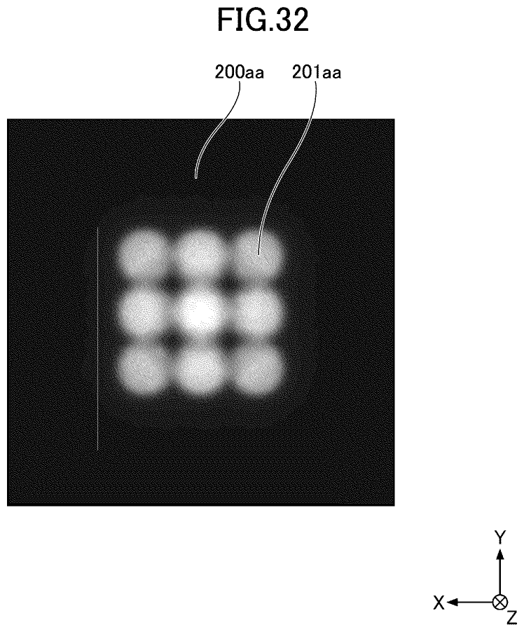

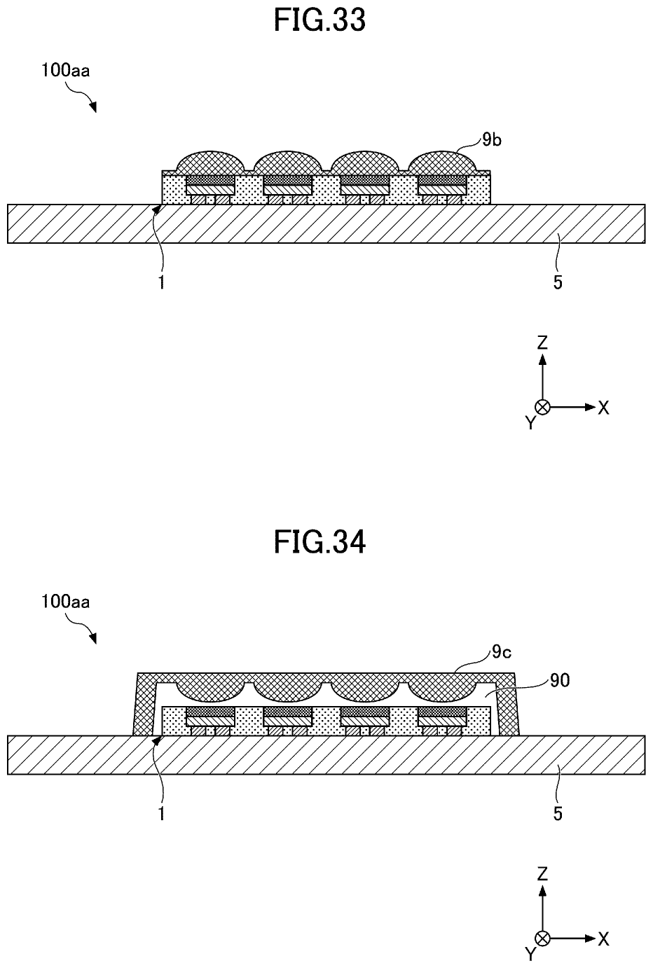

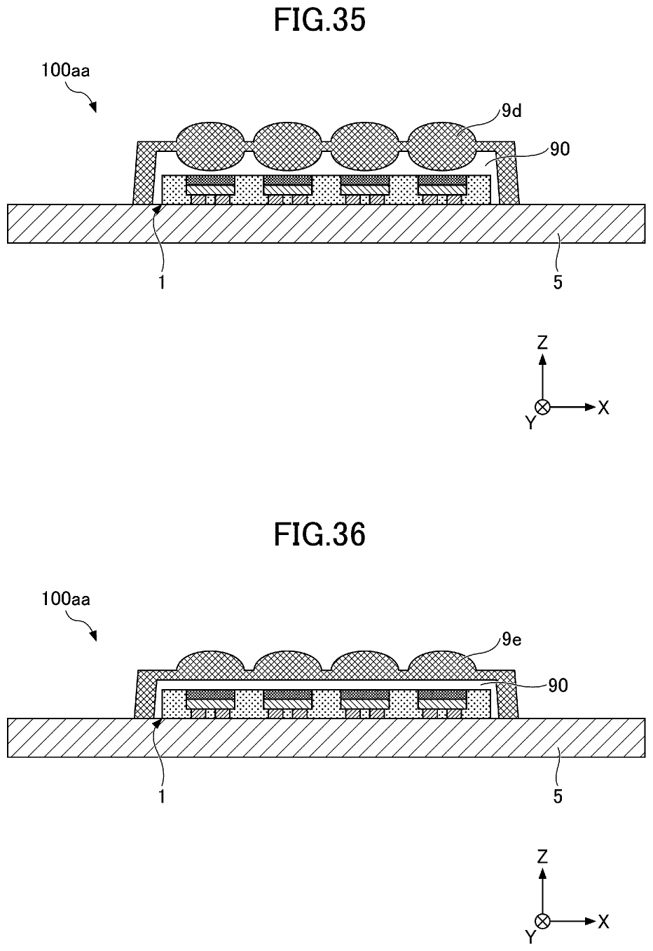

FIGS. 33 to 36 are cross-sectional views illustrating other modified examples of the second lenses. FIG. 33 illustrates a second modified example, FIG. 34 illustrates a third modified example, FIG. 35 illustrates a fourth modified example, and FIG. 36 illustrates a fifth modified example, respectively. FIGS. 33 to 36 illustrate the array light source 1, the second lenses 9, and the light-emitting unit mounting substrate 5 in the light-emitting device 100aa according to the modified examples of the second embodiment.

As illustrated in FIG. 33, a second lens 9b is a plano-convex lens having a flat surface on the side of the array light source 1 and a convex surface on the side opposite to the array light source 1. As the second lenses 9b, 16 second lenses 9b are arranged in an array pattern and are connected across the light-emitting units 10 to be formed as a single body.

As illustrated in FIG. 34, a second lens 9c is a plano-convex lens having a convex surface on the array light source 1 side and a flat surface on the side opposite to the array light source 1 side. As the second lenses 9c, 16 second lenses 9c arranged in an array pattern are connected across the light-emitting units 10 to be formed as a single body. An air layer 90 is provided between the second lens 9c and the array light source 1.

As illustrated in FIG. 35, a second lens 9d is a single biconvex lens having a convex surface on the array light source 1 side and a convex surface on the side opposite to the array light source 1 side. As the second lenses 9d, 16 second lenses 9d arranged in an array pattern are connected across the light-emitting units 10 to be formed as a single body. The air layer 90 is provided between the second lens 9d and the array light source 1.

As illustrated in FIG. 36, a second lens 9e is a plano-convex lens having a flat surface on the array light source 1 side and a convex surface on the side opposite to the array light source 1 side. As the second lenses 9e, 16 second lenses 9e arranged in an array pattern are connected across the light-emitting units 10 to be formed as a single body. The air layer 90 is provided between the second lens 9e and the array light source 1.

The second lenses 9b, 9c, 9d, and 9e can be manufactured by, for example, resin-injection molding or the like. As in the second lenses 9b, 9c, 9d, and 9e, by integrally forming the 16 second lenses, it is not necessary to individually manufacture and dispose the 16 second lenses, and thus it is possible to easily manufacture and dispose the 16 second lenses.

In addition, as in the second lenses 9c, 9d, and 9e, because an air layer is provided between the 16 second lenses and the array light source 1, control factors for the second lenses can be increased, and thus a design flexibility of the second lenses can be increased.

While configurations in which the number of the second lens is 16 have been exemplified, the number of the second lenses can be adjusted as appropriate according to the number of the light-emitting units 10.

### Modified Example

Various modified examples of the light-emitting device according to embodiments will be described.

### Modified Example of Movement Mechanism

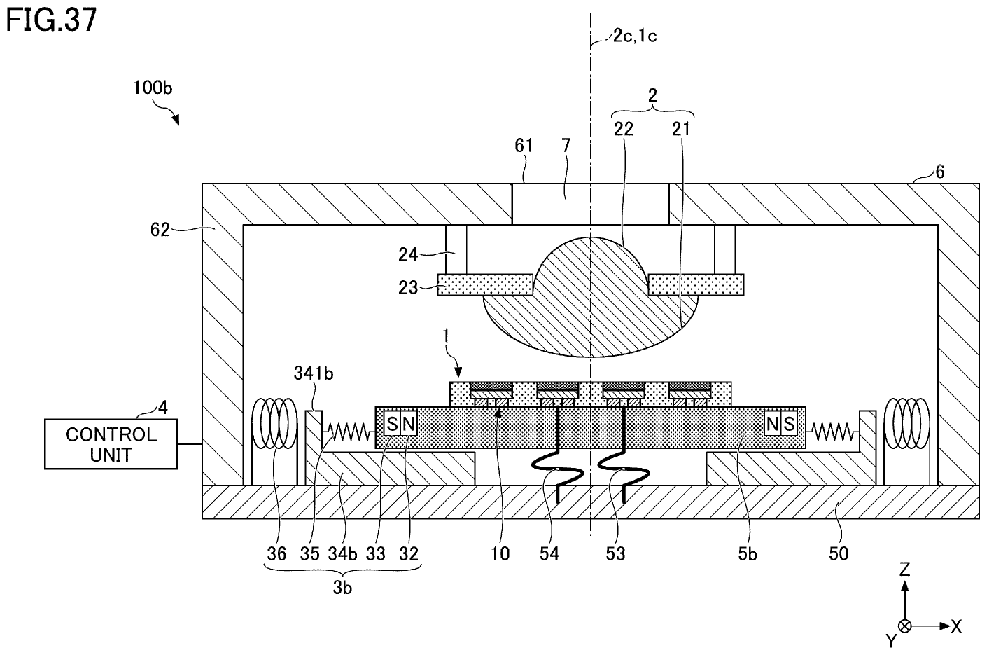

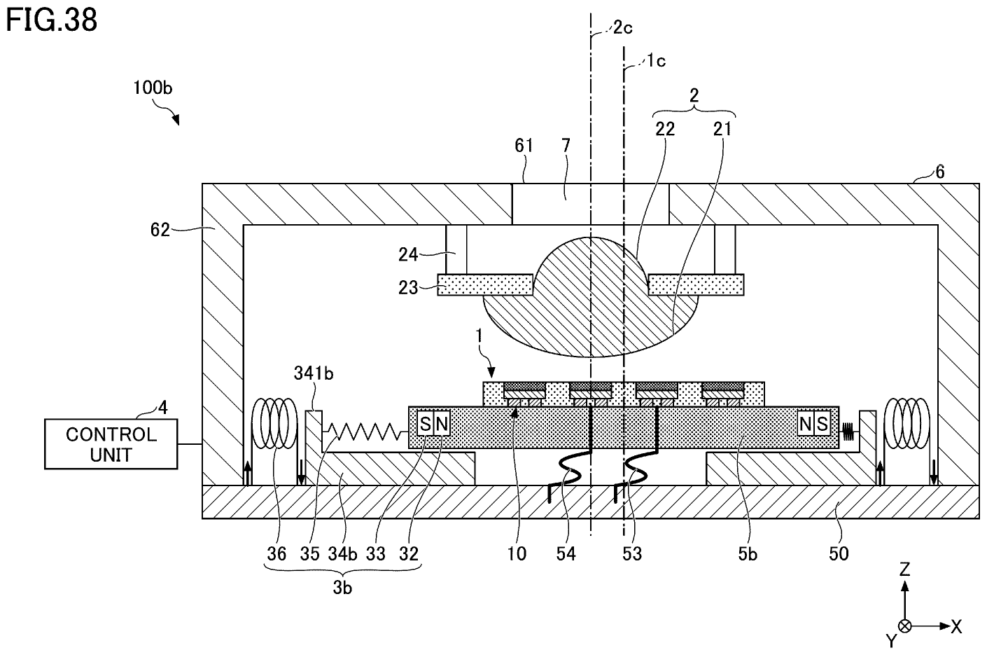

FIG. 37 is a cross-sectional view illustrating a modified example of the movement mechanism of the light-emitting device 100 according to an embodiment. FIG. 38 is a plan view illustrating a state after the array light source has moved to the +X direction side from the state of FIG. 37.

As illustrated in FIGS. 37 and 38, a light-emitting device 100b includes a movement mechanism 3b.

The movement mechanism 3b is an electromagnetic actuator that is provided on the +Z side of a wiring substrate 50 and is configured to cause the first lens 2 and the array light source 1 to move relative to each other along a direction intersecting with the optical axis 2c of the first lens 2. The movement mechanism 3b is configured to move the array light source 1 and thereby cause the first lens 2 and the array light source 1 to move relative to each other.

The movement mechanism 3b includes a light-emitting unit mounting substrate 5b and a platform portion 34b.

The light-emitting unit mounting substrate 5b is different from the light-emitting unit mounting substrate 5 only in that the N-pole magnets 32 and the S-pole magnets 33 are provided, and has the same function and configuration as the light-emitting unit mounting substrate 5 in other respects. The N-pole magnet 32 and the S-pole magnet 33 form a pair and, for example, four pairs of the N-pole magnet 32 and the S-pole magnet 33 are fixed inside respective sides of the light-emitting unit mounting substrate 5b.

The first lens 2 is fixed to the housing 6 via the first lens holding portion 23 and a support portion 24.

The platform portion 34b is a member having a substantially rectangular frame-like shape in a plan view. The platform portion 34b is fixed on the +Z-side surface of the wiring substrate 50 such that the array light source 1 fixed to the light-emitting unit mounting substrate 5b is internally disposed. The light-emitting unit mounting substrate 5b is movably mounted on the +Z-side surface of the platform portion 34b. A wall portion 341b is provided on the outer peripheral portion of the platform portion 34b, that is, a portion on the side opposite to the side facing the array light source 1.

The wiring substrate 50 is a plate-shaped member with a substantially rectangular shape in a plan view and is a substrate provided with an electrical wiring. The control unit 4 is configured to supply a drive signal to the movement mechanism 3b via the light-emitting unit mounting substrate 5, and supply a drive signal to the array light source 1 via the light-emitting unit mounting substrate 5b, a lead wire 53, and a lead wire 54.

The function and action of the movement mechanism 3b are similar to the function and action of the movement mechanism 3 except that the array light source 1 is moved. By moving the array light source 1 in this manner, the light-emitting device 100b can also cause the first lens 2 and the array light source 1 to move relative to each other. In this case, the first lens 2 is fixed, which allows the light-emitting device 100b to have a good appearance. The movement mechanism 3b can be applied to any of the light-emitting device 100, the light-emitting device 100a, and the light-emitting device 100aa.

### Modified Example of Array Light Source

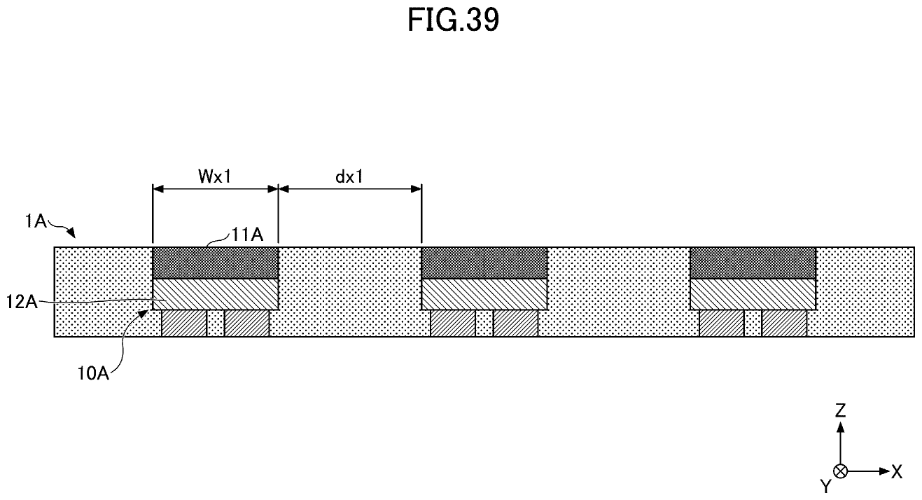

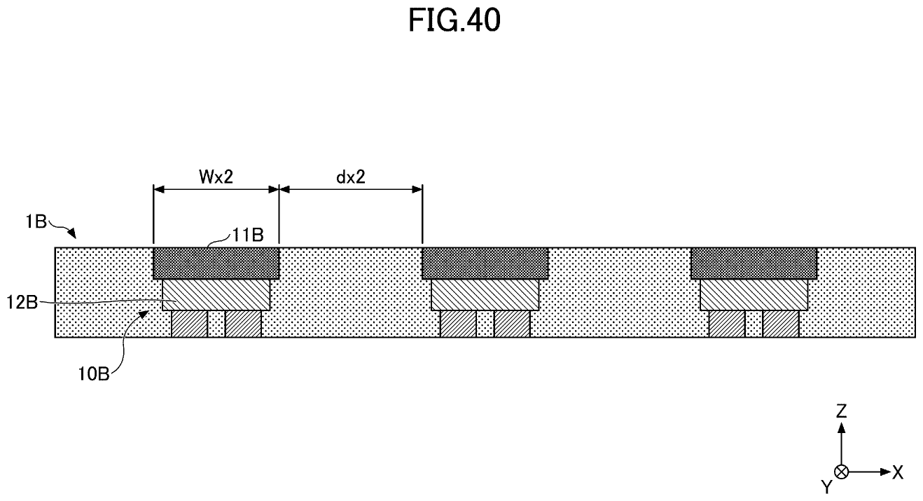

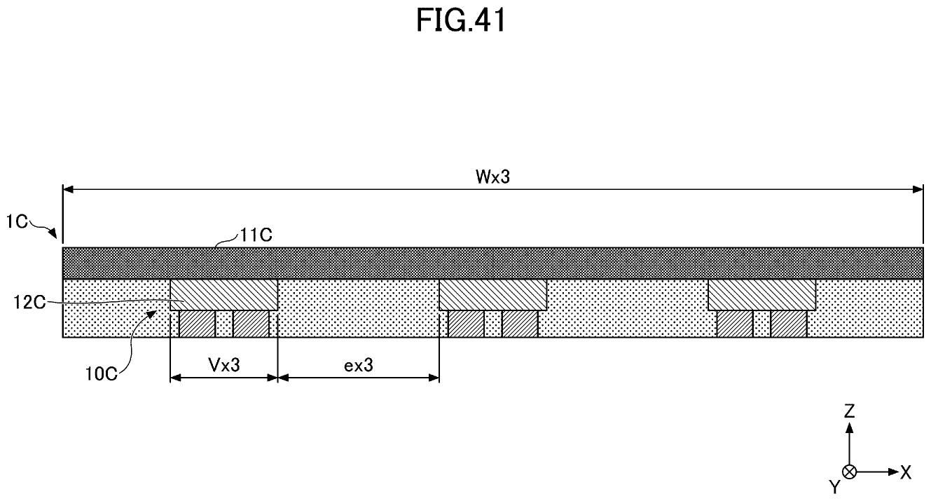

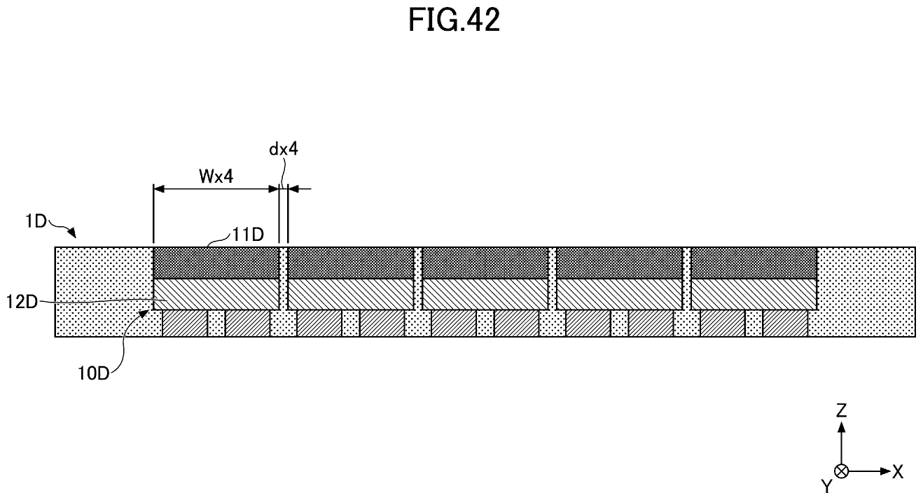

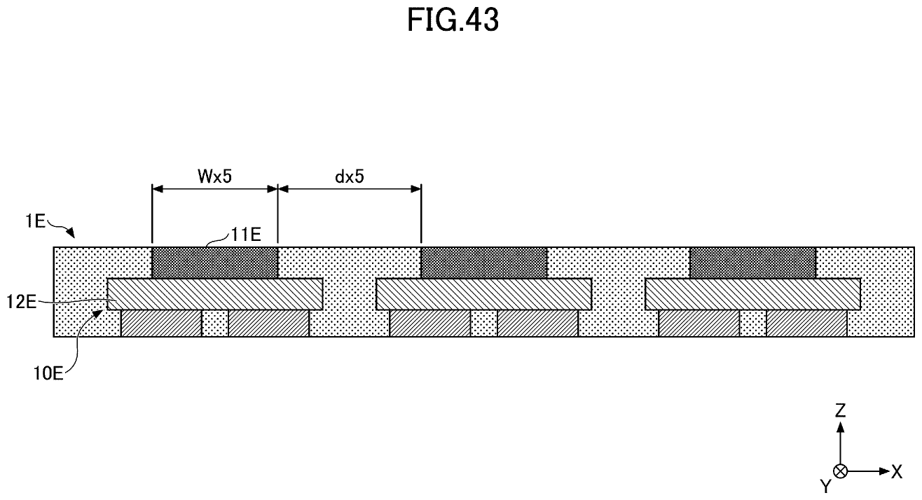

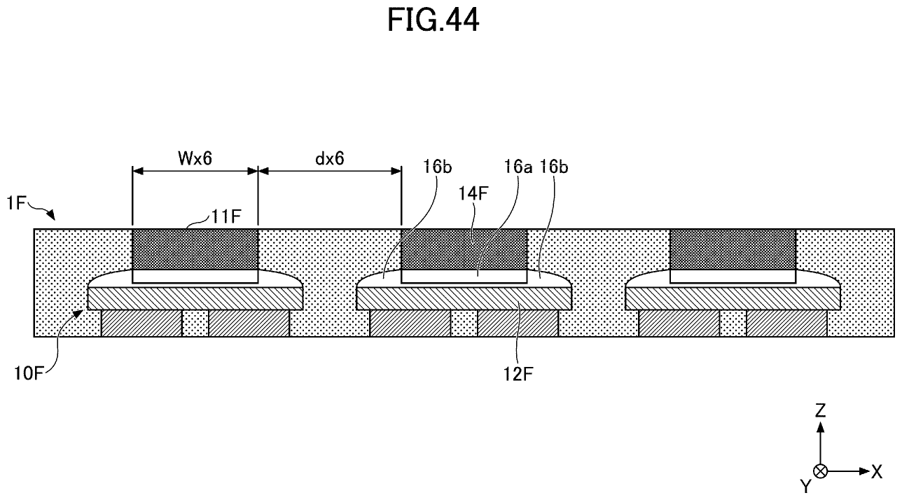

FIGS. 39 to 44 are cross-sectional views illustrating modified examples of the array light source of the light-emitting device 100 according to embodiments. FIG. 39 is a first modified example, FIG. 40 is a second modified example, FIG. 41 is a third modified example, FIG. 42 is a fourth modified example, FIG. 43 is a fifth modified example, and FIG. 44 is a sixth modified example. The configurations of the light-emitting device 100 other than the array light source are the same as the configurations illustrated in FIG. 2. Further, each modified example of the array light source can be applied to any of the light-emitting device 100a, the light-emitting device 100aa, and the light-emitting device 100b.

A width Vx represents the width along the X direction of each of the light-emitting units 10 arranged along the X direction.

A width Vy represents the width along the Y direction of each of the light-emitting units 10 arranged along the Y direction. A first light-emitting unit interval ex represents the interval along the X direction between adjacent light-emitting units 10. A second light-emitting unit interval ey represents the interval along the Y direction between adjacent light-emitting units 10.

The distance of the first relative movement and the distance of the second relative movement by the movement mechanism 3 or the movement mechanism 3b differ depending on the configuration of the array light source 1. In the following, the width of the light-emitting element 12, the width Wx of the light-emitting surface 11, the width Vx of the light-emitting unit 10, the first light-emitting surface interval dx, and the first light-emitting unit interval ex in the X direction will be described as an example, but the same applies to those in the Y direction except that the directions are different.

In an array light source 1A illustrated in FIG. 39, the length of a width Wx1 of a light-emitting surface 11A is substantially equal to the length of the first light-emitting surface interval dx1. In this case, the distance of the first relative movement is substantially equal to the length of the width Wx1 of the light-emitting surface 11A. The length of the width Wx1 of the light-emitting surface 11A is equal to the width of a light-emitting element 12A. In the array light source 1A, the length of the width Wy of the light-emitting surface 11A, the length of the second light-emitting surface interval dy, and the width of the light-emitting element 12A are substantially equal to each other.

In an array light source 1B illustrated in FIG. 40, a width Wx2 of a light-emitting surface 11B is longer than the width of a light-emitting element 12B.

The length of the width Wx2 of the light-emitting surface 11B is substantially equal to the length of the first light-emitting surface interval dx2. In this case, the distance of the first relative movement is substantially equal to or greater than the width Wx2 of the light-emitting surface 11B. In other words, the distance of the first relative movement is equal to or greater than the length of the shorter one of either the first light-emitting surface interval dx2 or the width Wx2 of the light-emitting surface 11B.

An array light source 1C illustrated in FIG. 41 includes a plurality of light-emitting units 10C arranged in an array pattern and a light-emitting surface 11C shared by two or more light-emitting units 10C among the plurality of light-emitting units 10C. Mutually adjacent light-emitting units 10C are disposed along the X direction at a first light-emitting unit interval ex3. A width Wx3 of the light-emitting surface 11C is longer than a width Vx3 of the light-emitting unit 10C. The length of the width Vx3 of the light-emitting unit 10C is shorter than the length of the first light-emitting unit interval ex3. In this case, the distance of the first relative movement is substantially equal to or greater than the width Vx3 of the light-emitting unit 10C. In other words, the distance of the first relative movement is equal to or greater than the length of the shorter one of either the first light-emitting unit interval ex3 or the width Vx3 of the light-emitting unit 10C. The width Vx3 of the light-emitting unit 10C is equal to the width of a light-emitting element 12C.

In an array light source 1D illustrated in FIG. 42, the length of a width Wx4 of a light-emitting surface 11D is substantially equal to the length of the width of a light-emitting element 12D. The length of the width Wx4 of the light-emitting surface 11D is longer than the length of the first light-emitting surface interval dx4. In this case, the distance of the first relative movement is substantially equal to or greater than the first light-emitting surface interval dx4. In other words, the distance of the first relative movement is equal to or greater than the length of the shorter one of either the first light-emitting surface interval dx4 or the width Wx4 of the light-emitting surface 11D. In such an array light source 1D, for example, when one light-emitting unit 10 is caused to emit light in a state before the first lens 2 relatively moves, the other light-emitting units 10 on a path on which the first lens 2 relatively moves are caused not to emit light, which suppresses overlapping of light beams emitted by the respective light-emitting units 10 with each other on the region to be irradiated 200.

In an array light source 1E illustrated in FIG. 43, the length of a width Wx5 of a light-emitting surface 11E is shorter than the length of the width of a light-emitting element 12E. The length of the width Wx5 of the light-emitting surface 11E is substantially equal to the length of the first light-emitting surface interval dx5. The length of the width of the light-emitting element 12E is longer than the length of the first light-emitting surface interval dx5. In this case, the distance of the first relative movement is substantially equal to or greater than the width Wx5 of the light-emitting surface 11E. In other words, the distance of the first relative movement is equal to or greater than the length of the shorter one of either the first light-emitting surface interval dx5 or the width Wx5 of the light-emitting surface 11E.

An array light source 1F illustrated in FIG. 44 includes a resin layer 16a and an adhesive member 16b between a light-transmitting member 14F and a light-emitting element 12F. The resin layer 16a is bonded to the light-transmitting member 14F, and a lateral surface and a lower surface of the resin layer 16a and an upper surface of the light-emitting element 12F are covered with the adhesive member 16b. For example, the resin layer 16a and the light-transmitting member 14F are bonded to each other by using the same resin material as a base material. The adhesive member 16b is, for example, an adhesive that bonds the resin layer 16a and the light-emitting element 12F. The resin layer 16a and the adhesive member 16b preferably have a light transmittance of 80% or more. In such an array light source 1F, even when the area of the light-emitting element 12F is smaller than the area of the light-transmitting member 14F in a plan view, light emitted from the light-emitting element 12F can be caused to be incident on the light-transmitting member 14F by the adhesive member 16b.

In the array light source 1F, the length of a width Wx6 of a light-emitting surface 11F is shorter than the length of the width of the light-emitting element 12F. The length of the width Wx6 of the light-emitting surface 11F is substantially equal to the length of the first light-emitting surface interval dx6. The length of the width of the light-emitting element 12F is longer than the length of the first light-emitting surface interval dx6. In this case, the distance of the first relative movement is substantially equal to or greater than the width Wx6 of the light-emitting surface 11F. In other words, the distance of the first relative movement is equal to or greater than the length of the shorter one of either the first light-emitting surface interval dx6 or the width Wx6 of the light-emitting surface 11F.

Even in the light-emitting device 100 having any one of the array light sources 1A to 1F as described above, it is possible to control a region to be partially irradiated with light in the region to be irradiated 200 and to obtain natural partial irradiation light by increasing the number of divisions of the region to be irradiated 200.

In the light-emitting device 100 including the array light source 1C, the plurality of light-emitting units 10 are disposed along the X direction, or disposed along the X direction and the Y direction. With this configuration, partial irradiation can be performed two dimensionally in the region to be irradiated 200.

In addition, in the light-emitting device 100 including the array light source 1C, the control unit 4 performs control so as to compensate for the illuminance of the region corresponding to the first light-emitting unit interval ex in the region to be irradiated 200.

By this control, the light-emitting device 100 can perform partial irradiation while suppressing the dark portion 202 corresponding to the first light-emitting unit interval ex in the region to be irradiated 200, and can increase the number of divisions of the region to be irradiated 200 while avoiding illuminance unevenness in the region to be irradiated 200.

In addition, in the light-emitting device 100 including the array light source 1C, each of the first light-emitting unit intervals ex is preferably in a range from 0.05 [mm] to 2.00 [mm]. With this configuration, it is possible to achieve both of obtaining good light emission characteristics and an interval at which the plurality of light-emitting units 10 are mountable, and it is possible to increase the number of divisions of the region to be irradiated 200 under conditions in which the light-emitting units 10 can be easily mounted.

In the light-emitting device 100 including the array light source 1C, the relative movement further includes the second relative movement in which the first lens 2 and the array light source 1 move relative to each other along the Y direction orthogonal to the X direction, and mutually adjacent light-emitting units 10 are disposed along the Y direction at the second light-emitting unit interval ey. The distance of the second relative movement is equal to or greater than the length of the shorter one of either the second light-emitting unit interval ey or the width Wy of the light-emitting surface 11 along the Y direction. With this configuration, it is possible to increase the number of the light-emitting units 10 in a pseudo manner in both directions of the X and Y directions in light irradiation within the exposure period Ts. As a result of that, it is possible to provide the light-emitting device 100 that can more precisely control the region to be partially irradiated with light in the region to be irradiated 200.

### Modified Example of Relative Movement Path

In the first embodiment described above, the relative movement path in which the first lens 2 moves in the +X direction from the first state to become the second state, the first lens 2 moves in the +Y direction from the second state to become the third state, the first lens 2 moves in the −X direction from the third state to become the fourth state, and the first lens 2 moves in the −Y direction from the fourth state to return to the first state has been described. Here, the term “relative movement path” means a route of cyclic movement of the first lens 2 and the array light source 1 relative to each other within the exposure period.

This relative movement path can also be modified in various ways.

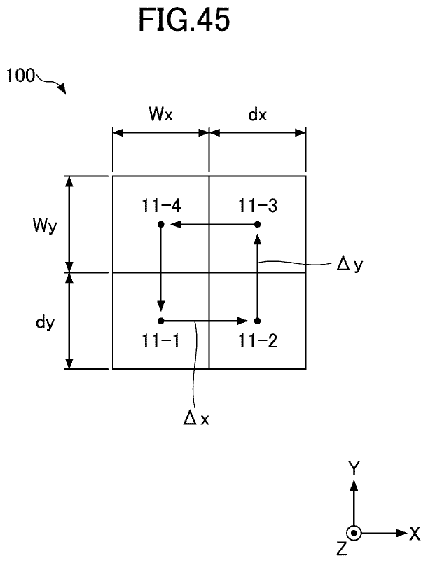

FIG. 45 is a diagram for describing a first modified example of the relative movement path in the light-emitting device 100. FIG. 45 illustrates the relative movement path in a case in which the length of the first light-emitting surface interval dx is substantially equal to the length of the width Wx of the light-emitting surface 11, and the length of the second light-emitting surface interval dy is equal to the length of the width Wy of the light-emitting surface 11. When irradiation is performed without causing the first lens 2 to relatively move, as illustrated in FIG. 13 and the like, the dark portion 202 is generated in the region to be irradiated 200 corresponding to a region in which the light-emitting surface 11 is not disposed in the array light source 1.

In the light-emitting device 100, the distance Δx of the intermittent first relative movement of the first lens 2 per one time is made substantially equal to the width Wx of the light-emitting surface 11, and the distance Δy of the intermittent second relative movement of the first lens 2 per one time is made substantially equal to the width Wx of the light-emitting surface 11. By performing the intermittent relative movement of the first lens 2 four times in total within the exposure period Ts, the light-emitting device 100 can irradiate the dark portion 202 of the region to be irradiated 200 with light from the light-emitting surface 11 and compensate for the dark portion 202.

The operation of compensating for the dark portion 202 is equivalent to the movement of the light-emitting surface 11 to a position on the array light source 1 at which the light-emitting surface 11 is not disposed in response to the relative movement of the first lens 2. Therefore, FIG. 45 schematically illustrates how the light-emitting surface 11 apparently moves in each of the X direction and the Y direction. Hereinafter, the apparent movement of the light-emitting surface 11 will be simply referred to as the movement of the light-emitting surface 11.

The first light-emitting surface interval dx is substantially equal to the width Wx of the light-emitting surface 11, the first relative movement includes two first intermittent relative movements, and the distance Δx of the intermittent first relative movement per one time is substantially equal to the width Wx of the light-emitting surface 11. The second light-emitting surface interval dy is substantially equal to the width Wy of the light-emitting surface 11, the second relative movement includes two second intermittent relative movements, and the distance Δy of the intermittent second relative movement per one time is substantially equal to the width Wy of the light-emitting surface 11.

In addition, the first relative movement includes two first intermittent relative movements, and the second relative movement includes two second intermittent relative movements. The relative movement between the first lens 2 and the array light source 1 is an intermittent relative movement that is performed four times including the first intermittent relative movement and the second intermittent relative movement. When the distance of the intermittent relative movement is ΔW, the distance ΔW satisfies the following Formula (1).

$$Δ W \leq √ ( {Wx}^{2} + {Wy}^{2} ) \qquad ( 1 )$$

In FIG. 45, a position 11-1 represents the position of the center of the light-emitting surface 11 in the first state. A position 11-2 represents the position of the center of the light-emitting surface 11 in the second state. A position 11-3 represents the position of the center of the light-emitting surface 11 in the third state. A position 11-4 represents the position of the center of the light-emitting surface 11 in the fourth state. The light-emitting device 100 causes the first lens 2 to perform a round-trip movement within the exposure period Ts such that the center of the light-emitting surface 11 moves to the position 11-1, the position 11-2, the position 11-3, and the position 11-4 in this order and then returns to the position 11-1.

For example, when the difference in the moving distance for each intermittent relative movement per one time increases, illuminance variation, such as flickering, becomes conspicuous in the region to be irradiated 200 in some cases. When the first lens 2 is caused to relatively move so as to correspond to the path illustrated in FIG. 45, the distance ΔW of the intermittent relative movement satisfies the above-described Formula (1), and as a result, it is possible to suppress the difference in the moving distance for each intermittent relative movement per one time and suppress illuminance variation, such as flickering, in the region to be irradiated 200.

However, the relative movement path is not limited to that illustrated in FIG. 45. For example, the first lens 2 may perform the relative movement such that the center of the light-emitting surface 11 moves to the position 11-1, the position 11-2, the position 11-3, and the position 11-4 in this order in the predetermined exposure period Ts, and then move from the position 11-4 to the position 11-3, the position 11-2, and the position 11-1 in the reverse direction in the subsequent exposure period Ts. Also in this case, because the above-described Formula (1) is satisfied and the difference in the moving distance for each intermittent relative movement per one time can be suppressed, it is possible to suppress illuminance variation, such as flickering, in the region to be irradiated 200.

The distance Δx of the intermittent first relative movement per one time need not necessarily be equal to the width Wx of the light-emitting surface 11, and a length that is equal to or greater than the width Wx of the light-emitting surface 11 is sufficient. Similarly, the distance Δy of the intermittent second relative movement per one time need not necessarily be equal to the width Wy of the light-emitting surface 11, and a length equal to or greater than the width Wy of the light-emitting surface 11 is sufficient. However, from the viewpoint of suppressing the illuminance variation, it is preferable that the distance ΔW of the intermittent relative movement is determined so as to satisfy the above-described Formula (1). That is, when the first light-emitting surface interval dx is longer than the width Wx of the light-emitting surface 11, it is preferable that the following Formula (2) is satisfied.

$$Wx \times Δ W \leq √ ( {Wx}^{2} + {Wy}^{2} ) \qquad ( 2 )$$

In addition, when the second light-emitting surface interval dy is longer than the width Wy of the light-emitting surface 11, it is preferable to satisfy the following Formula (3).

$$Wy \leq Δ W \leq √ ( {Wx}^{2} + {Wy}^{2} ) \qquad ( 3 )$$

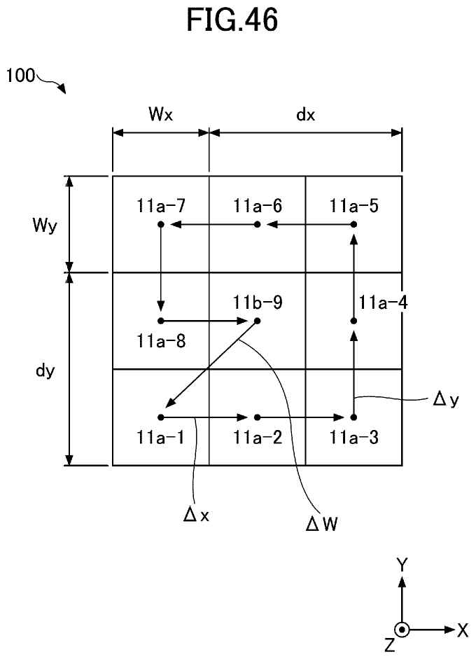

FIG. 46 is a diagram for describing a second modified example of the relative movement path. In FIG. 46, the length of the first light-emitting surface interval dx is approximately twice the length of the width Wx of the light-emitting surface 11, and the length of the second light-emitting surface interval dy is approximately twice the length of the width Wy of the light-emitting surface 11.

In the light-emitting device 100, the distance Δx of the intermittent first relative movement of the first lens 2 per one time is made substantially equal to the width Wx of the light-emitting surface 11, and the distance Δy of the intermittent second relative movement of the first lens 2 per one time is made substantially equal to the width Wx of the light-emitting surface 11. However, the distance ΔW of the relative movement satisfies √(Wx²+Wy²) only when returning from the position 11a-9 to the position 11a-1, which is the initial position.

The light-emitting device 100 causes the first lens 2 to perform a round-trip movement within the exposure period Ts such that the center of the light-emitting surface 11 moves to the position 11a-1, the position 11a-2, the position 11a-3, the position 11a-4, the position 11a-5, the position 11a-6, the position 11a-7, the position 11a-8, and the position 11a-9 in this order, and then returns to the position 11a-1. By such a round-trip movement, the light-emitting device 100 can irradiate the dark portion 202 of the region to be irradiated 200 with light from the light-emitting surface 11 to compensate for the dark portion 202.

In the relative movement path illustrated in FIG. 46, the number of times of the intermittent relative movement within the exposure period Ts is nine in total.

In other words, the first relative movement includes five first intermittent relative movements, and the second relative movement includes three second intermittent relative movements. The relative movement between the first lens 2 and the array light source 1 is an intermittent relative movement that is performed nine times including the first intermittent relative movement and the second intermittent relative movement. The distance ΔW of the intermittent relative movement satisfies the above-described Formula (1). As a result of that, in the relative movement path illustrated in FIG. 46, the difference in the moving distance for each intermittent relative movement per one time can be suppressed to a minimum, and the light-emitting device 100 can suppress illuminance variation, such as flickering, in the region to be irradiated 200.

For example, the first lens 2 may perform the relative movement such that the center of the light-emitting surface 11 moves to the position 11a-1, the position 11a-2, the position 11a-3, the position 11a-4, the position 11a-5, the position 11a-6, the position 11a-7, the position 11a-8, and the position 11a-9 in this order in a predetermined exposure period Ts, and then moves from the position 11a-9 to the position 11a-1 in the reverse direction along the order of the reference signs in the subsequent exposure period Ts. Also in this case, because the above-described Formula (1) can be satisfied and the difference in the moving distance for each intermittent relative movement per one time can be suppressed, it is possible to suppress illuminance variation, such as flickering, in the region to be irradiated 200.

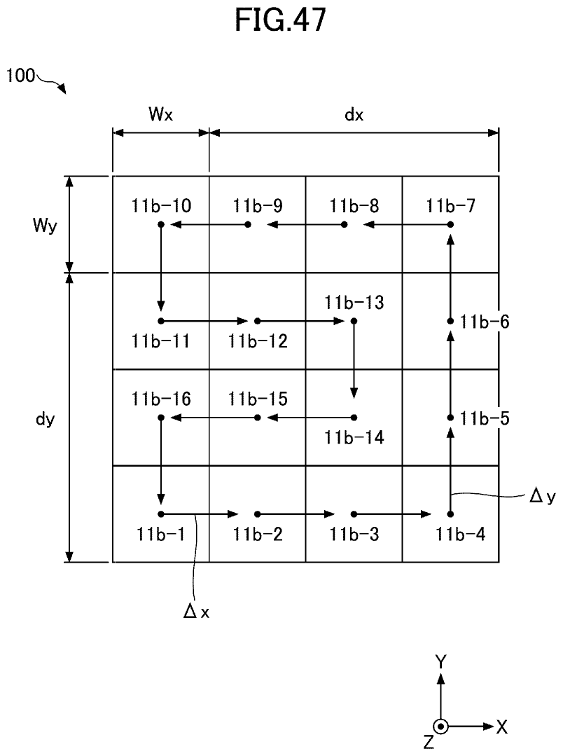

FIG. 47 is a diagram for describing a third modified example of the relative movement path. In FIG. 47, the length of the first light-emitting surface interval dx is approximately three times the length of the width Wx of the light-emitting surface 11, and the length of the second light-emitting surface interval dy is approximately three times the length of the width Wy of the light-emitting surface 11.

In the light-emitting device 100, the distance Δx of the intermittent first relative movement of the first lens 2 per one time is made substantially equal to the width Wx of the light-emitting surface 11, and the distance Δy of the intermittent second relative movement of the first lens 2 per one time is made substantially equal to the width Wx of the light-emitting surface 11. The light-emitting device 100 causes the first lens 2 to perform a round-trip movement such that the center of the light-emitting surface 11 moves from the position 11b-1 to the position 11b-16 in the order of the reference signs, and then returns to the position 11b-1 within the exposure period Ts. Thus, the light-emitting device 100 can irradiate the dark portion 202 of the region to be irradiated 200 with light from the light-emitting surface 11 to compensate for the dark portion 202.

In the relative movement path illustrated in FIG. 47, the number of times of the intermittent relative movement within the exposure period Ts is 16 in total. Because the number of times of movement is an even number of times, similarly to the relative movement path illustrated in FIG. 45 in which the number of times of movement is the same even number of times, the light-emitting device 100 can suppress the difference in the moving distance for each intermittent relative movement per one time and suppress illuminance variation, such as flickering, in the region to be irradiated 200. The effect on the illuminance variation is the same in any case of the even number of times of movement.

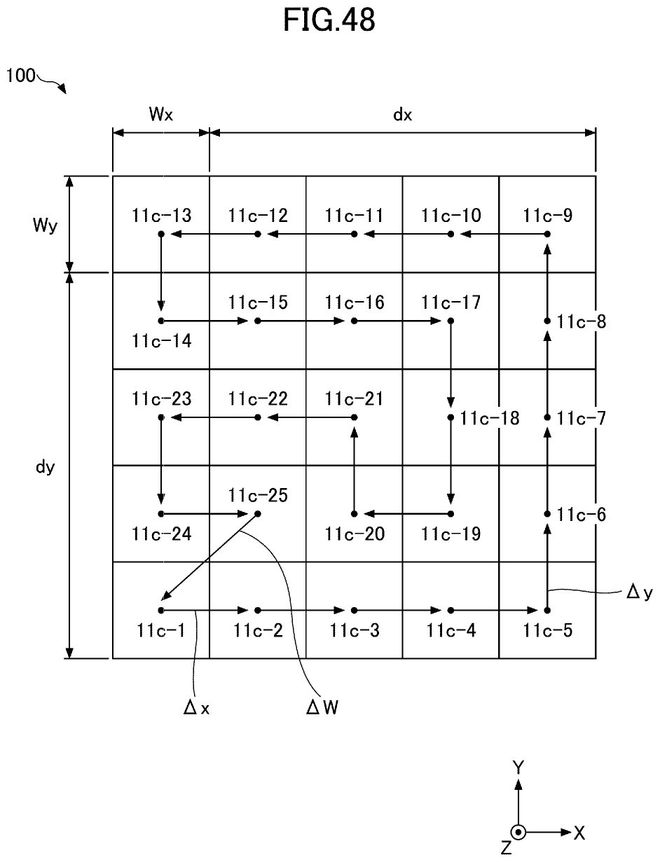

FIG. 48 is a diagram for describing a fourth modified example of the relative movement path. In FIG. 48, the length of the first light-emitting surface interval dx is approximately four times the length of the width Wx of the light-emitting surface 11, and the length of the second light-emitting surface interval dy is approximately four times the length of the width Wy of the light-emitting surface 11.

In the light-emitting device 100, the distance Δx of the intermittent first relative movement of the first lens 2 per one time is made substantially equal to the width Wx of the light-emitting surface 11, and the distance Δy of the intermittent second relative movement of the first lens 2 per one time is made substantially equal to the width Wx of the light-emitting surface 11. However, the distance ΔW of the relative movement satisfies √(Wx²+Wy²) only when returning from the position 11c-25 to the position 11c-1, which is the initial position.

The light-emitting device 100 causes the first lens 2 to perform a round-trip movement such that the center of the light-emitting surface 11 moves from the position 11c-1 to the position 11c-25 in the order of the reference signs, and then returns to the position 11c-1 within the exposure period Ts. By such a round-trip movement, the light-emitting device 100 can irradiate the dark portion 202 of the region to be irradiated 200 with light from the light-emitting surface 11 to compensate for the dark portion 202.

In the relative movement path illustrated in FIG. 48, the number of times of the intermittent relative movement within the exposure period Ts is 25 in total. Because the number of times of movement is an odd number of times, similarly to the relative movement path illustrated in FIG. 46 in which the number of times of movement is the same odd number of times, the light-emitting device 100 can suppress the difference in the moving distance for each intermittent relative movement per one time and suppress illuminance variation, such as flickering, in the region to be irradiated 200. The effect on the illuminance variation is the same in any case of the odd number of times of movement.

In FIGS. 45 to 48, a configuration in which the width Wx of the light-emitting surface 11, the width Wy of the light-emitting surface 11, the first light-emitting surface interval dx, and the second light-emitting surface interval dy are used in the relative movement has been described as an example. However, the same applies to a configuration including a plurality of light-emitting units 10C arranged in an array pattern and the light-emitting surface 11C shared by two or more light-emitting units 10C among the plurality of light-emitting units 10C, such as the array light source 1C illustrated in FIG. 41, that is a configuration using the width Vx of the light-emitting unit 10 along the X direction, the width Vy of the light-emitting unit 10 along the Y direction, the first light-emitting unit interval ex and the second light-emitting unit interval ey.

That is, the first light-emitting unit interval ex is longer than the width Vx of the light-emitting unit 10 along the X direction, the first relative movement includes a plurality of first intermittent relative movements, and the distance Δx of the intermittent first relative movement per one time is equal to or greater than the width Vx of the light-emitting unit 10 along the X direction. The second light-emitting unit interval ey is longer than the width Vy of the light-emitting unit 10 along the Y direction, the second relative movement includes a plurality of second intermittent relative movements, and the distance Δy of the intermittent second relative movement per one time is equal to or greater than the width Vy of the light-emitting unit 10 along the Y direction. With this configuration, the light-emitting device 100 can irradiate the dark portion 202 of the region to be irradiated 200 with light from the light-emitting surface 11 to compensate for the dark portion 202.

Further, the first relative movement includes a plurality of first intermittent relative movements, and the second relative movement includes a plurality of second intermittent relative movements. The relative movement between the first lens 2 and the array light source 1 is a plurality of intermittent relative movements including the first intermittent relative movement and the second intermittent relative movement. When the distance of the intermittent relative movement is ΔV the distance ΔV satisfies the following Formula (4).

$$Δ V \leq √ ( {Vx}^{2} + {Vy}^{2} ) \qquad ( 4 )$$

Accordingly, the light-emitting device 100 can suppress the difference in the moving distance for each intermittent relative movement per one time and suppress illuminance variation, such as flickering, in the region to be irradiated 200.

When the first light-emitting unit interval ex is longer than the width Vx of the light-emitting unit 10, it is preferable that the distance ΔV of the intermittent relative movement satisfies the following Formula (5).

$$Vx \leq Δ V \leq √ ( {Vx}^{2} + {Vy}^{2} ) \qquad ( 5 )$$

In addition, when the second light-emitting unit interval ey is longer than the width Vy of the light-emitting unit 10, it is preferable that the distance ΔV of the intermittent relative movement satisfies the following Formula (6).

$$Vy \leq Δ V \leq √ ( {Vx}^{2} + {Vy}^{2} ) \qquad ( 6 )$$

While preferred embodiments have been described in detail above, the disclosure is not limited to the above-described embodiments, various modifications and substitutions can be made to the above-described embodiments without departing from the scope described in the claims.

The number, quantity, and the like used in the description of the embodiments all are exemplified to specifically describe the technology of the present disclosure, and the present disclosure is not limited to the numbers exemplified. In addition, the connection relationship between the components is exemplified for specifically describing the technique of the present disclosure, and the connection relationship for realizing the function of the present disclosure is not limited thereto.

The light-emitting device of the present disclosure can irradiate a desired partial irradiation region with light, and thus can be suitably used for illumination, the flash of a camera, headlights on a vehicle, and the like. However, the light-emitting device of the present disclosure is not limited to these uses.

The present disclosure includes the following aspects.

### Aspect 1

A light-emitting device includes: an array light source including a plurality of light-emitting units arranged in an array pattern; a first lens configured cause light emitted by the array light source to irradiate a region to be irradiated; a movement mechanism configured to cause the first lens and the array light source to move relative to each other along a direction intersecting with an optical axis of the first lens; and a control unit including: a light emission control unit configured to control light emission of each of the plurality of light-emitting units, and a movement control unit configured to control an operation of the movement mechanism. The light emission control unit is configured to control light emission of each of the plurality of light-emitting units within a predetermined period. The movement control unit is configured to control the operation of the movement mechanism such that the first lens and the array light source perform a relative movement within the predetermined period. The relative movement includes a first relative movement in which the first lens and the array light source move relative to each other along a first direction. Each of the plurality of light-emitting units has a light-emitting surface. The light-emitting surfaces of adjacent ones of the light-emitting units are located at a first light-emitting surface interval therebetween. A distance of the first relative movement is equal to or greater than a length of a shorter one of either the first light-emitting surface interval or a width of the light-emitting surface along the first direction.

### Aspect 2

The light-emitting device according to Aspect 1, wherein
the plurality of light-emitting units are disposed along the first direction, or disposed along the first direction and a second direction orthogonal to the first direction.

### Aspect 3

The light-emitting device according to Aspect 1 or 2, wherein
the control unit is configured to perform control so as to compensate for an illuminance of a region corresponding to the first light-emitting surface interval in the region to be irradiated.

### Aspect 4

The light-emitting device according to any one of Aspects 1 to 3, wherein
the first light-emitting surface interval is in a range from 0.05 [mm] to 2.00 [mm].

### Aspect 5

The light-emitting device according to any one of Aspects 1 to 4, wherein
the first light-emitting surface interval is longer than the width of the light-emitting surface along the first direction,
the first relative movement comprises a plurality of first intermittent relative movements, and
a distance of the intermittent first relative movement per one time is equal to or greater than the width of the light-emitting surface along the first direction.

### Aspect 6

The light-emitting device according to any one of Aspects 1 to 5, wherein
the relative movement further comprises a second relative movement in which the first lens and the array light source move relative to each other along a second direction orthogonal to the first direction,
the light-emitting surfaces of adjacent ones of the light-emitting units are arranged along the second direction at a second light-emitting surface interval, and
a distance of the second relative movement is equal to or greater than a length of a shorter one of either the second light-emitting surface interval or a width of the light-emitting surface along the second direction.

### Aspect 7

The light-emitting device according to Aspect 6, wherein
the second light-emitting surface interval is longer than a width of the light-emitting surface along the second direction,
the second relative movement comprises a plurality of second intermittent relative movements, and
a distance of the intermittent second relative movement per one time is equal to or greater than the width of the light-emitting surface along the second direction.

### Aspect 8

The light-emitting device according to any one of Aspects 1 to 7, wherein
the first relative movement comprises a plurality of first intermittent relative movements,
a second relative movement in which the first lens and the array light source move relative to each other along a second direction orthogonal to the first direction comprises a plurality of second intermittent relative movements,
the relative movement is a plurality of intermittent relative movements comprising the first intermittent relative movements and the second intermittent relative movements, and
when the width of the light-emitting surface along the first direction is Wx, a width of the light-emitting surface along the second direction is Wy, and a distance of the intermittent relative movement is ΔW, the light-emitting device satisfies the following formula.

$$Δ W \leq √ ( {Wx}^{2} + {Wy}^{2} )$$

### Aspect 9

A light-emitting device comprising:
an array light source comprising:
   a plurality of light-emitting units arranged in an array pattern, and
   a light-emitting surface shared by two or more light-emitting units of the plurality of light-emitting units;
   a first lens configured to cause light emitted by the array light source to irradiate a region to be irradiated;
   a movement mechanism configured to cause the first lens and the array light source to move relative to each other along a direction intersecting with an optical axis of the first lens; and
   a control unit comprising:
   a light emission control unit configured to control light emission of each of the plurality of light-emitting units, and
   a movement control unit configured to control an operation of the movement mechanism, wherein
   the light emission control unit is configured to control light emission of each of the plurality of light-emitting units within a predetermined period,
   the movement control unit is configured to control the operation of the movement mechanism such that the first lens and the array light source perform a relative movement within the predetermined period,
   the relative movement comprises a first relative movement in which the first lens and the array light source move relative to each other along a first direction,
   adjacent ones of the light-emitting units are disposed along the first direction at a first light-emitting unit interval, and
   a distance of the first relative movement is equal to or greater than a length of a shorter one of either the first light-emitting unit interval or a width of the light-emitting unit along the first direction.

### Aspect 10

The light-emitting device according to Aspect 9, wherein
the plurality of light-emitting units are disposed along the first direction, or disposed along the first direction and a second direction orthogonal to the first direction.

### Aspect 11

The light-emitting device according to Aspect 9 or 10, wherein
the control unit is configured to perform control so as to compensate for an illuminance of a region corresponding to the first light-emitting unit interval in the region to be irradiated.

### Aspect 12

The light-emitting device according to any one of Aspects 9 to 11, wherein
each of the first light-emitting unit intervals is in a range from 0.05 [mm] to 2.00 [mm].

### Aspect 13

The light-emitting device according to any one of Aspects 9 to 12, wherein
the first light-emitting unit interval is longer than the width of the light-emitting unit along the first direction,
the first relative movement comprises a plurality of first intermittent relative movements, and
a distance of the intermittent first relative movement per one time is equal to or greater than the width of the light-emitting unit along the first direction.

### Aspect 14

The light-emitting device according to any one of Aspects 9 to 13, wherein
the relative movement further comprises a second relative movement in which the first lens and the array light source move relative to each other along a second direction orthogonal to the first direction,
the light-emitting units that are mutually adjacent are disposed along the second direction at a second light-emitting unit interval, and
a distance of the second relative movement is equal to or greater than a length of a shorter one of either the second light-emitting unit interval or a width of the light-emitting surface along the second direction.

### Aspect 15

The light-emitting device according to Aspect 14, wherein
the second light-emitting unit interval is longer than a width of the light-emitting unit along the second direction,
the second relative movement comprises a plurality of second intermittent relative movements, and
a distance of the intermittent second relative movement per one time is equal to or greater than the width of the light-emitting unit along the second direction.

### Aspect 16

The light-emitting device according to any one of Aspects 9 to 15, wherein
the first relative movement comprises a plurality of first intermittent relative movements,
a second relative movement in which the first lens and the array light source move relative to each other along a second direction orthogonal to the first direction comprises a plurality of second intermittent relative movements,
the relative movement is a plurality of intermittent relative movements comprising the first intermittent relative movement and the second intermittent relative movement, and
when the width of the light-emitting unit along the first direction is Vx, a width of the light-emitting unit along the second direction is Vy, and a distance of the intermittent relative movement is ΔV, the light-emitting device satisfies the following formula.

$$Δ V \leq √ ( {Vx}^{2} + {Vy}^{2} )$$

### Aspect 17

The light-emitting device according to any one of Aspects 1 to 16, wherein
the relative movement is a plurality of intermittent relative movements, and
the light emission control unit performs control such that the plurality of light-emitting units do not emit light while the intermittent relative movement is performed one time.

### Aspect 18

The light-emitting device according to any one of Aspects 1 to 17, wherein
the light emission control unit controls switching of the light-emitting unit that performs the light emission among the plurality of light-emitting units and/or intensity of the light emitted by the light-emitting unit.

### Aspect 19

The light-emitting device according to any one of Aspects 1 to 18, wherein
a position at which the light-emitting unit is disposed and an irradiation position of the light emission performed by the light-emitting unit are in a point-symmetrical positional relationship with respect to an optical center of the first lens as a center of symmetry, the irradiation being performed by the first lens.

### Aspect 20

The light-emitting device according to any one of Aspects 1 to 19, comprising
a plurality of second lenses each disposed in pair with a respective one of the plurality of light-emitting units, wherein
the plurality of second lenses are provided between the first lens and the array light source.

### Aspect 21

The light-emitting device according to Aspect 20, wherein
the plurality of second lenses are formed as a single body.

### Aspect 22

The light-emitting device according to Aspect 20 or 21, wherein
an air layer is provided between the plurality of second lenses and the array light source.

### Aspect 23

The light-emitting device according to any one of Aspects 1 to 20, wherein
the light-emitting device is a flash light source to be used in an imaging device, and
the predetermined period is equal to either one of an imaging cycle or an exposure period of the imaging device.

This application claims priority based on Japanese Patent Application No. 2021-207832, filed with the Japan Patent Office on Dec. 22, 2021, the entire contents of which are included herein by reference.

1. A light-emitting device comprising:
an array light source comprising a plurality of light-emitting units arranged in an array pattern, each light-emitting unit including a light-emitting surface, wherein the light-emitting surfaces of adjacent ones of the light-emitting units are located at a first light-emitting surface interval;
a first lens configured to cause light emitted by the array light source to irradiate a region to be irradiated;
a movement mechanism configured to cause the first lens and the array light source to move relative to each other along a direction intersecting an optical axis of the first lens; and
a control unit comprising one or more electrical circuits or one or more central processing units, the control unit configured to:
control light emission of each of the plurality of light-emitting units in a predetermined period, and
control operation of the movement mechanism such that the first lens and the array light source perform a relative movement within the predetermined period, wherein the relative movement comprises a first relative movement in which the first lens and the array light source move relative to each other along a first direction, and wherein a distance of the first relative movement is equal to or greater than a length of a shorter one of either (i) the first light-emitting surface interval or (ii) a width of one of the light-emitting surfaces along the first direction.

2. The light-emitting device according to claim 1, wherein:
the plurality of light-emitting units are disposed along the first direction, or disposed along the first direction and a second direction orthogonal to the first direction.

3. The light-emitting device according to claim 1, wherein:
the control unit is configured to control operation of the movement mechanism so as to compensate for an illuminance of a region corresponding to the first light-emitting surface interval in the region to be irradiated.

4. The light-emitting device according to claim 1, wherein:
the first light-emitting surface interval is in a range from 0.05 mm to 2.00 mm.

5. The light-emitting device according to claim 1, wherein:
the first light-emitting surface interval is longer than the width of said one of the light-emitting surfaces along the first direction,
the first relative movement comprises a plurality of first intermittent relative movements, and
a distance of each of the first intermittent relative movements is equal to or greater than the width of said one of the light-emitting surfaces along the first direction.

6. The light-emitting device according to claim 1, wherein:
the relative movement further comprises a second relative movement in which the first lens and the array light source move relative to each other along a second direction orthogonal to the first direction,
the light-emitting surfaces of adjacent ones of the light-emitting units are arranged along the second direction at a second light-emitting surface interval, and
a distance of the second relative movement is equal to or greater than a length of a shorter one of either (i) the second light-emitting surface interval or (ii) a width of said one of the light-emitting surfaces along the second direction.

7. The light-emitting device according to claim 6, wherein:
the second light-emitting surface interval is longer than a width of said one of the light-emitting surfaces along the second direction,
the second relative movement comprises a plurality of second intermittent relative movements, and
a distance of each of the second intermittent relative movements is equal to or greater than the width of said one of the light-emitting surfaces along the second direction.

8. The light-emitting device according to claim 1, wherein:
the first relative movement comprises a plurality of first intermittent relative movements,
the relative movement further comprises a second relative movement in which the first lens and the array light source move relative to each other along a second direction orthogonal to the first direction,
the second relative movement comprises a plurality of second intermittent relative movements, and
when the width of the light-emitting surface along the first direction is Wx, a width of the light-emitting surface along the second direction is Wy, and a distance of the intermittent relative movement is ΔW, the light-emitting device satisfies the following formula:
$$Δ W \leq √ ( {Wx}^{2} + {Wy}^{2} ) .$$

9. The light-emitting device according to claim 1, wherein:
the relative movement comprises a plurality of intermittent relative movements, and
the control unit is configured to control the light emission such that the plurality of light-emitting units do not emit light while the intermittent relative movement is performed one time.

10. The light-emitting device according to claim 1, wherein:
the control unit is configured to control switching of the light-emitting unit that performs the light emission among the plurality of light-emitting units and/or an intensity of the light emitted by the plurality of light-emitting units.

11. The light-emitting device according to claim 1, wherein:
a position at which each light-emitting unit is disposed and an irradiation position of the light emission performed by that light-emitting unit via the first lens are in a point-symmetrical positional relationship with respect to an optical center of the first lens as a center of symmetry.

12. The light-emitting device according to claim 1, further comprising:
a plurality of second lenses each disposed in a pair with a respective one of the plurality of light-emitting units, wherein:
the plurality of second lenses are located between the first lens and the array light source.

13. The light-emitting device according to claim 12, wherein:
the plurality of second lenses are formed as a single body.

14. The light-emitting device according to claim 12, wherein:
an air layer is located between the plurality of second lenses and the array light source.

15. The light-emitting device according to claim 1, wherein:
the light-emitting device is a flash light source to be used in an imaging device, and
the predetermined period is equal to either one of (i) an imaging cycle or (ii) an exposure period of the imaging device.

16. A light-emitting device comprising:
an array light source comprising:
a plurality of light-emitting units arranged in an array pattern, wherein adjacent ones of the light-emitting units are disposed along a first direction at a first light-emitting unit interval, and
a light-emitting surface shared by two or more light-emitting units of the plurality of light-emitting units;
a first lens configured to cause light emitted by the array light source to irradiate a region to be irradiated;
a movement mechanism configured to cause the first lens and the array light source to move relative to each other along a direction intersecting with an optical axis of the first lens; and
a control unit comprising one or more electrical circuits or one or more central processing units, the control unit configured to:
control light emission of each of the plurality of light-emitting units in a predetermined period, and
control operation of the movement mechanism such that the first lens and the array light source perform a relative movement within the predetermined period, wherein the relative movement comprises a first relative movement in which the first lens and the array light source move relative to each other along the first direction, and wherein a distance of the first relative movement is equal to or greater than a length of a shorter one of either (i) the first light-emitting unit interval or (ii) a width of one of the light-emitting units along the first direction.

17. The light-emitting device according to claim 16, wherein:
the plurality of light-emitting units are disposed along the first direction, or disposed along the first direction and a second direction orthogonal to the first direction.

18. The light-emitting device according to claim 16, wherein:
the control unit is configured to control operation of the movement mechanism so as to compensate for an illuminance of a region corresponding to the first light-emitting unit interval in the region to be irradiated.

19. The light-emitting device according to claim 16, wherein:
each of the first light-emitting unit intervals is in a range from 0.05 mm to 2.00 mm.

20. The light-emitting device according to claim 16, wherein:
the first light-emitting unit interval is longer than the width of said one of the light-emitting units along the first direction,
the first relative movement comprises a plurality of first intermittent relative movements, and
a distance of each of the first intermittent relative movements is equal to or greater than the width of said one of the light-emitting units along the first direction.

21. The light-emitting device according to claim 16, wherein:
the relative movement further comprises a second relative movement in which the first lens and the array light source move relative to each other along a second direction orthogonal to the first direction,
the light-emitting units that are mutually adjacent are disposed along the second direction at a second light-emitting unit interval, and
a distance of the second relative movement is equal to or greater than a length of a shorter one of either (i) the second light-emitting unit interval or (i) a width of said one of the light-emitting units along the second direction.

22. The light-emitting device according to claim 21, wherein
the second light-emitting unit interval is longer than a width of said one of the light-emitting units along the second direction,
the second relative movement comprises a plurality of second intermittent relative movements, and
a distance of each of the second intermittent relative movements is equal to or greater than the width of said one of the light-emitting units along the second direction.

23. The light-emitting device according to claim 16, wherein:
the first relative movement comprises a plurality of first intermittent relative movements,
the relative movement further comprises a second relative movement in which the first lens and the array light source move relative to each other along a second direction orthogonal to the first direction comprises a plurality of second intermittent relative movements, and
when the width of the light-emitting unit along the first direction is Vx, a width of the light-emitting unit along the second direction is Vy, and a distance of the intermittent relative movement is ΔV, the light-emitting device satisfies the following formula:
$$Δ V \leq √ ( {Vx}^{2} + {Vy}^{2} ) .$$
